(19) United States
(12) Patent Application Publication
(10) Pub. No.: US 2010/0219437 A1
(43) Pub. Date: Sep. 2, 2010

(54) NITRIDE SEMICONDUCTOR LIGHT EMITTING DIODE

(76) Inventors: Manabu Usuda, Osaka (JP); Kazuhiko Yamanaka, Osaka (JP)

Correspondence Address: MCDERMOTT WILL & EMERY LLP, 600 13TH STREET, NW, WASHINGTON, DC, 20005-3096, US

(21) Appl. No.: 12/682,143

(22) PCT Filed: Aug. 28, 2009
(86) PCT No.: PCT/JP2009/004203

§ 371 Date: Apr. 8, 2010

(30) Foreign Application Priority Data
Oct. 6, 2008 (JP) 2008-259290
Feb. 27, 2009 (JP) 2009-045842

(51) Int. Cl. H01L 33/10; H01L 33/30; H01L 33/00

(52) U.S. Cl. 257/98; 257/103; 257/E33.023; 257/E33.005; 257/E33.067

(57) ABSTRACT

A nitride semiconductor light emitting diode includes a p-type layer 103 made of a p-type nitride semiconductor, a light emission layer 102 provided on a lower surface of the p-type layer 103, an n-type layer 101 made of an n-type nitride semiconductor provided on a lower surface of the light emission layer 102, and a bonding layer 114 provided, contacting the n-type layer 101. An uneven topography having a plurality of sloped surface is provided on a surface contacting the bonding layer 114 of the n-type layer 101. The bonding layer 114 is made of a metal made of Group III atoms or an alloy containing the Group III atoms.

### TECHNICAL FIELD

The technology disclosed herein relates to single-sided electrode type or p-side up electrode type light emitting diodes made of a nitride-based Group III-V semiconductor.

### BACKGROUND ART

In recent years, the development of light emitting diodes having high light emission efficiency has been rapidly advanced, and technologies for applying such light emitting diodes to, for example, backlight sources for liquid crystal display devices, such as liquid crystal televisions and the like, have been actively developed. Among such light emitting diodes, light emitting diodes made of a nitride semiconductor, typified by GaN (gallium nitride) (referred to hereinafter as nitride semiconductor light emitting diodes, or simply as light emitting diodes) can particularly emit light having a wavelength ranging from ultraviolet to blue, and therefore, can emit white light in combination with a fluorescent material. Therefore, nitride semiconductor light emitting diodes are essential for light sources, such as a liquid crystal backlight and the like. In such a circumstance, a light emitting diode having a higher luminance is strongly desired so as to meet a recent demand for higher-luminance liquid crystal display devices.

Conventionally, such nitride semiconductor light emitting diodes are typically fabricated by a method of epitaxially growing a nitride semiconductor layer including a light emission layer on a substrate, such as a sapphire substrate or a SiC substrate. The structure of electrodes in nitride semiconductor light emitting diodes employing a sapphire substrate or a SiC substrate varies depending on the substrate.

For example, in nitride semiconductor light emitting diodes employing a sapphire substrate, as the sapphire substrate is an insulating substrate, the light emitting diodes typically have a structure in which a p-electrode and an n-electrode are both formed on the light emitting surface (the nitride semiconductor layer) of the light emitting diode (this structure is referred to hereinafter as a single-sided electrode type). In this case, the light emitting diode is packaged by a method of fixing the sapphire substrate onto the lead frame of the package using a resin adhesive or the like, and coupling the p-electrode and the n-electrode to a wiring portion of the lead frame using a Au wire. On the other hand, nitride semiconductor light emitting diodes employing a conductive SiC substrate typically have a structure in which only the p-electrode is formed on the light emitting surface of the light emitting diode, while the n-electrode is formed on the back surface of the SiC substrate, and light is generated by passing a current in a vertical direction of the light emitting diode structure (this structure is referred to hereinafter as a p-side up electrode type). In this case, the light emitting diode is packaged by a method of fixing the SiC substrate onto an n-electrode wiring portion of the lead frame using a conductive resin, such as a silver paste or the like, and coupling the p-electrode to a p-electrode wiring portion of the lead frame using a Au wire.

For such single-sided electrode type or p-side up electrode type nitride semiconductor light emitting diodes, various techniques for efficiently extracting light from the light emission portion of the light emitting diode to the outside of the light emitting diode have been proposed so as to increase the luminance. Specifically, for example, a technique of providing a reflective surface between a nitride semiconductor layer on which the light emitting surface of the light emitting diode is formed, and a substrate so that light which is emitted from the light emitting surface toward the substrate is reflected toward the light emitting surface, thereby improving a light extraction efficiency, has been proposed. As used herein, the light extraction efficiency refers to an efficiency with which light emitted from the light emission portion of a light emitting diode is extracted to the outside of the light emitting diode.

Structures of conventional nitride semiconductor light emitting diodes will be described with reference to FIGS. 26 and 27.

FIG. 26 is a cross-sectional view showing a structure of a light emitting diode 800 described in Patent Document 1 or Non-Patent Document 1 as a conventional example (referred to hereinafter as Conventional Example 1).

As shown in FIG. 26, the light emitting diode 800 of Conventional Example 1 includes a conductive support substrate 815 as the lowest layer. A reflective layer 814 constituting a reflective surface 821 is formed on the support substrate 815. An n-type layer 801 made of an n-type nitride semiconductor, a light emission layer 802, and a p-type layer 803 made of a p-type nitride semiconductor are stacked in this stated order on the reflective layer 814 to form a nitride semiconductor layer 804. Moreover, a transparent electrode 811 constituting a light emitting surface 820 is formed on the upper surface of the p-type layer 803, and a p-electrode 812 is formed on a portion of the upper surface of the transparent electrode 811. A p-side up electrode type structure is thus formed. In this structure, light emitted from the light emission layer 802 toward the light emitting surface 820 is transmitted through the transparent electrode 811 and is then emitted to the outside of the light emitting diode. On the other hand, a portion of light emitted from the light emission layer 802 which travels in an opposite direction from the light emitting surface 820, is reflected toward the light emitting surface 820 by the reflective surface 821. As a result, the light extraction efficiency is improved, whereby the luminance of the light emitting diode is improved.

Moreover, a technique of further improving the light emission efficiency of the aforementioned light emitting diode having a reflective surface has been proposed. Specifically, in the light emitting diode of Conventional Example 1, most of light which travels downward and obliquely with respect to the reflective surface repeatedly undergoes total reflection in the nitride semiconductor layer 804, and eventually is not emitted from the light emitting surface and is absorbed by the nitride semiconductor layer 804, resulting in an insufficient improvement in the light extraction efficiency. Therefore, a structure having an uneven reflective surface has been proposed as in, for example, Patent Document 2.

FIG. 27 is a cross-sectional view showing a structure of a light emitting diode 900 described in Patent Document 2 as a conventional example (referred to hereinafter as Conventional Example 2).

As shown in FIG. 27, the light emitting diode 900 of Conventional Example 2 includes a conductive support substrate 915 as the lowest layer, where a backside electrode 916 is provided on a lower surface of the conductive support substrate 915. A second metal layer 914, a first metal layer 913, and a contact layer 912 are formed on the support substrate 915. Moreover, a p-type layer 903, a light emission layer 902, and an n-type layer 901 are formed in this stated order on the contact layer 912 to form a nitride semiconductor layer 904. An n-electrode 911 is formed on a portion of the upper surface of the n-type layer 901, and the upper surface of the n-type layer 901 constitutes a light emitting surface 920. The contact layer 912 is made of a nitride semiconductor which has a lower band gap than that of the p-type layer 903. A fine uneven topography is formed on a surface contacting the first metal layer 913 of the contact layer 912 using a dry etching method. Therefore, a reflective surface 921 formed of the first metal layer 913 has an uneven surface. By thus providing the uneven surface on the reflective surface, light emitted from the light emission layer toward the reflective surface undergoes diffuse reflection on the reflective surface having the uneven surface so that the light turns in various different directions. Therefore, the proportion of light which travels horizontally in the nitride semiconductor layer 904 and repeatedly undergoes total reflection is reduced. As a result, light which is emitted upward from the light emitting diode is increased, whereby the light extraction efficiency is improved compared to the structure of Conventional Example 1.

Patent Document 2 describes a method for fabricating the light emitting diode of Conventional Example 2. In this method, an n-type layer, a light emission layer, and a p-type layer are epitaxially grown in this stated order on a base substrate, such as a sapphire substrate, a SiC substrate, or the like, before an uneven topography is formed in the uppermost surface of the p-type layer by a dry etching method. Thereafter, a support substrate is joined with the upper surface of the p-type layer in which the uneven topography is formed, via a reflective layer and a bonding metal layer, by a substrate bonding technique. Thereafter, the base substrate is removed to expose a surface of the n-type layer, and an n-electrode is formed on a portion of the exposed surface of the n-type layer. Thus, the light emitting diode of Conventional Example 2 is fabricated.

### CITATION LIST

### Patent Document

PATENT DOCUMENT 1: Japanese Patent Laid-Open Publication No. 2004-88083

PATENT DOCUMENT 2: Japanese Patent Laid-Open Publication No. 2007-123573

### Non-Patent Document

NON-PATENT DOCUMENT 1: Japanese Journal of Applied Physics Vol. 43, No. 8A, 2004, pp 5239-5242

### SUMMARY OF THE INVENTION

### Technical Problem

However, the conventional structures of Conventional Examples 1 and 2 have the following problems.

Firstly, the structure of Conventional Example 2 has a problem that the arrangement of the electrodes is different from that of the structure of conventional light emitting diodes which employ a sapphire substrate or a SiC substrate. Specifically, the light emitting diode of Conventional Example 2 has a so-called n-side up electrode type structure in which an n-electrode is formed on the light emitting surface. Therefore, in this case, a packaging method needs to be modified so that the support substrate is fixed onto a p-electrode wire of a lead frame using a conductive resin, and the n-electrode of the light emitting diode is coupled to an n-electrode wire of the lead frame using a Au wire. This modification requires package design and fabrication different from those for conventional light emitting diodes employing a sapphire substrate or a SiC substrate, resulting in an increase in the cost of the backlight source.

To avoid such a cost increase, the light emitting diode of Conventional Example 1 may be used in which the conventional package structure can be used without modification. However, the structure of Conventional Example 1 has the aforementioned problem that the light extraction efficiency is not sufficient, and in addition, a problem with adhesiveness that the reflective layer is likely to delaminate the nitride semiconductor layer including the light emission portion, and a problem that the operating voltage of the light emitting diode increases. The present inventors actually fabricated the light emitting diode of Conventional Example 1 to find that there was a problem that the nitride semiconductor layer and the reflective layer were delaminated from each other in a chip separation step after the reflective layer and the support substrate were formed on the nitride semiconductor layer. Also in the case of the light emitting diode structure in which the reflective layer is formed as described in Non-Patent Document 1, there is a problem that the operating voltage increases by about 0.5-1 V compared to the structure in which a reflective layer is not formed.

Among the aforementioned problems, one with the light extraction efficiency may be overcome by providing an uneven topography in the reflective surface as described in Conventional Example 2 while maintaining the electrode arrangement and the layer structure of Conventional Example 1 to improve the light extraction efficiency. In this case, the uneven topography may be formed in a surface of the n-type GaN layer using a dry etching method as in Conventional Example 2. Also in this case, however, the problem that the adhesiveness between the nitride semiconductor layer and the reflective layer is poor and the problem that the operating voltage increases are not overcome, as in Conventional Example 1.

In view of the aforementioned problems, it is an object of the present invention to provide a single-sided electrode type or p-side up type nitride semiconductor light emitting diode including a p-electrode formed on a light emitting surface, which has a structure which provides a high light extraction efficiency and reduces or prevents an increase in operating voltage. It is another object of the present invention to provide a structure which provides a high adhesiveness between a reflective layer constituting a reflective surface and a nitride semiconductor layer.

### Solution to the Problem

To achieve the object, an illustrative nitride semiconductor light emitting diode according to the present invention includes a p-type layer made of a p-type nitride semiconductor, a light emission layer provided on a lower surface of the p-type layer, an n-type layer made of an n-type nitride semiconductor, provided on a lower surface of the light emission layer, and a bonding layer provided, contacting the n-type layer. An uneven topography having a plurality of sloped surfaces is provided on a surface contacting the bonding layer of the n-type layer. The bonding layer is made of a metal made of Group III atoms or an alloy containing the Group III atoms. In this structure, a reflective surface is provided by the bonding layer.

In the illustrative nitride semiconductor light emitting diode of the present invention, an uneven topography having a plurality of sloped surfaces is provided on a surface contacting the bonding layer of the n-type layer. As a result, the reflective surface provided by the bonding layer has an uneven surface. Therefore, the light extraction efficiency can be improved by the diffuse reflection of light by the uneven surface.

The uneven surface is preferably a crystal face of a nitride semiconductor. Among such crystal faces, {1-10-1} planes, which are a kind of semipolar plane of nitride semiconductors, are particularly most preferable. As used herein, the semipolar plane refers to a plane which is sloped with respect to the c-plane, i.e., the (0001) plane. The braces { } indicate a group of planes having the same relative relationship with respect to the coordinate axes of crystal. The {1-10-1} planes include six equivalent planes, i.e., the (1-10-1), (10-1-1), (01-1-1), (−110-1), (−101-1), and (0-11-1) planes. The {1-10-1} planes can be easily formed by a wet etching method in which an aqueous potassium hydroxide (KOH) solution is used in combination with irradiation with ultraviolet light.

On the {1-10-1} planes, a topmost surface terminated with Group III atoms, such as Ga atoms or the like, is formed. The Group III atom in the topmost surface does not have a bond with a nitrogen atom, and therefore, is a negative ion having one more electron than it has protons, and therefore, the n-type carrier concentration effectively increases in the topmost surface, so that the contact resistance between the topmost surface and the bonding layer can be reduced. Therefore, the increase in the operating voltage can be reduced or prevented by the structure of the illustrative nitride semiconductor light emitting diode of the present invention.

Moreover, in the illustrative nitride semiconductor light emitting diode of the present invention, a material constituting the bonding layer is made of a metal made of Group III atoms or an alloy containing the Group III atoms. In this case, Group III atoms constituting the bonding layer, and Group III atoms constituting the topmost surface of the n-type GaN layer, such as Ga or the like, easily react with each other, so that surface reconstruction occurs. Therefore, a chemical bonding strength between the nitride semiconductor layer and the bonding layer increases. As a result, the adhesiveness between the n-type GaN layer and the bonding layer is significantly improved.

Note that, as the Group III atom which is a material constituting the bonding layer, a material which reflects, with a high efficiency, light which is emitted from the light emission layer and has a wavelength within the range of about 350 nm to about 550 nm, is preferable. In particular, Al or an alloy thereof is most preferable as such a material.

Moreover, the illustrative nitride semiconductor light emitting diode of the present invention may further include a reflective layer provided, contacting a lower portion of the bonding layer. The bonding layer may have a thickness which is smaller than or equal to a penetration depth with respect to light emitted from the light emission layer. In this case, as a material constituting the reflective layer, a metal which reflects light emitted from the light emission layer with a high efficiency is preferable. In particular, a metal made of Ag or an alloy containing Ag is most preferably as such a material.

With such a structure, the thickness of the bonding layer is smaller than or equal to the penetration depth of light. Therefore, light traveling from the light emission layer toward the bonding layer is transmitted through the bonding layer and reaches a surface of the reflective layer, and is reflected on the reflective layer surface. Therefore, if the reflective layer is made of a material having a high reflectance, such as Ag, the light reflection efficiency can be improved, resulting in a further increase in the luminance of the nitride semiconductor light emitting diode.

Moreover, the illustrative nitride semiconductor light emitting diode of the present invention may further include a dielectric layer formed between the n-type layer and the bonding layer, and having a plurality of openings. The n-type layer and the bonding layer may contact each other via the openings.

In this case, as the dielectric layer, a material having a small imaginary part of the complex refractive index, i.e., a small extinction coefficient is preferably used for the purpose of reduction or prevention of light absorption. Examples of such a material include SiO₂, TiO₂, MgF₂, CaF₂, SiₓN_{y}, AlₓO_{y}, LiF, and the like. The dielectric layer may be formed of a multilayer dielectric film in which two materials having a large difference in refractive index, such as SiO₂ and TiO₂, or the like, selected from the aforementioned dielectric materials, are alternately stacked. In this case, a portion of light emitted from the light emission layer toward the substrate is reflected on a surface of the dielectric layer, and light which is transmitted through the dielectric layer is also reflected on the bonding layer provided on a lower surface of the dielectric layer. Therefore, light can be reflected on the interface of the dielectric layer with a higher efficiency, resulting in an increase in the luminance of the light emitting diode. Alternatively, the dielectric layer may be formed of a dielectric material having a refractive index sufficiently lower than that of nitride semiconductors for the wavelength of light emitted from the light emitting diode. Examples of such a material include SiO₂, TiO₂, MgF₂, CaF₂, SiₓN_{y}, AlₓO_{y}, LiF, and the like. In this case, a portion of light emitted from the light emission layer toward the bonding layer is reflected without absorption because of the difference in refractive index between the nitride semiconductor and the dielectric layer, and light which is transmitted through the dielectric layer is also reflected on the bonding layer provided on the lower surface of the dielectric layer. Therefore, the light reflection efficiency can be improved, resulting in a further increase in the luminance of the light emitting diode.

Moreover, a plurality of openings may be provided in the dielectric layer. In this case, the n-type layer and the bonding layer contact each other via the openings, thereby allowing electrical conduction therebetween. In addition, the nitride semiconductor and the bonding layer are chemically coupled with each other, whereby the adhesiveness between the n-type layer and the bonding layer can be maintained.

### ADVANTAGES OF THE INVENTION

As described above, according to the illustrative nitride semiconductor light emitting diode of the present invention, a high light extraction efficiency is achieved, and the increase in the operating voltage is reduced or prevented. Moreover, a single-sided electrode type or p-side up electrode type nitride semiconductor light emitting diode is achieved in which the adhesiveness between the reflective layer and the nitride semiconductor layer is high. Moreover, according to the illustrative nitride semiconductor light emitting diode of the present invention, as the p-electrode is formed on the light emitting surface, the illustrative nitride semiconductor light emitting diode of the present invention and conventional nitride semiconductor light emitting diodes can employ a common package structure. Therefore, the luminance of the nitride semiconductor light emitting diode is increased without changing the package design.

### BRIEF DESCRIPTION OF THE DRAWINGS

FIG. 1(a) is a top view of a nitride semiconductor light emitting diode according to a first embodiment of the present invention. FIG. 1(b) is a cross-sectional view taken along line 1b-1b of FIG. 1(a).

FIGS. 2(a)-2(e) are cross-sectional views of the nitride semiconductor light emitting diode of the first embodiment of the present invention in the order in which the device is fabricated.

FIGS. 3(a)-3(d) are cross-sectional views of the nitride semiconductor light emitting diode of the first embodiment of the present invention in the order in which the device is fabricated.

FIG. 4 is a diagram showing an image of an uneven surface of the nitride semiconductor light emitting diode of the first embodiment of the present invention which was observed by a high-resolution electron microscope.

FIG. 5(a) is a schematic diagram for describing an atomic arrangement in the (1-10-1) plane of the nitride semiconductor light emitting diode of the first embodiment of the present invention. FIG. 5(b) is a schematic diagram for describing an atomic arrangement in the (000-1) plane of conventional nitride semiconductors.

FIG. 6 is a diagram for describing the flow of a current in the nitride semiconductor light emitting diode of the first embodiment of the present invention.

FIG. 7 is a diagram for describing trajectories of generated light in the nitride semiconductor light emitting diode of the first embodiment of the present invention.

FIG. 8 is a diagram showing light emitting diodes (a)-(c) which were fabricated to test an adhesiveness and an operating voltage in the first embodiment of the present invention.

FIG. 9 is a diagram showing total flux output-current characteristics of the nitride semiconductor light emitting diode of the first embodiment of the present invention, in comparison with the conventional art.

FIG. 10 is a diagram showing the nitride semiconductor light emitting diode of the first embodiment of the present invention after chip separation, in comparison with the conventional art.

FIG. 11 is a diagram showing current-voltage characteristics of the nitride semiconductor light emitting diode of the first embodiment of the present invention, in comparison with the conventional art.

FIG. 12(a) is a top view of an example package structure when the nitride semiconductor light emitting diode of the first embodiment of the present invention is used. FIG. 12(b) is a cross-sectional view taken along line XIIb-XIIb of FIG. 12(a).

FIG. 13(a) is a top view of a nitride semiconductor light emitting diode according to a second embodiment of the present invention. FIG. 13(b) is a cross-sectional view taken along line XIIIb-XIIIb of FIG. 13(a).

FIGS. 14(a)-14(d) are cross-sectional views of the nitride semiconductor light emitting diode of the second embodiment of the present invention in the order in which the device is fabricated.

FIG. 15 is a diagram for describing the flow of a current in the nitride semiconductor light emitting diode of the second embodiment of the present invention.

FIG. 16(a) is a top view of an example package structure when the nitride semiconductor light emitting diode of the second embodiment of the present invention is used. FIG. 16(b) is a cross-sectional view taken along line XVIb-XVIb of FIG. 16(a).

FIG. 17 is a cross-sectional view showing a structure of a nitride semiconductor light emitting diode according to a third embodiment of the present invention.

FIG. 18 is a diagram for describing a penetration depth of light in the metal Al in the third embodiment of the present invention.

FIG. 19 is a cross-sectional view showing a structure of a nitride semiconductor light emitting diode according to a fourth embodiment of the present invention.

FIGS. 20(a)-20(c) are cross-sectional views showing a first method for fabricating the nitride semiconductor light emitting diode of the fourth embodiment of the present invention in the order in which the device is fabricated.

FIGS. 21(a)-21(c) are cross-sectional views showing the first method for fabricating the nitride semiconductor light emitting diode of the fourth embodiment of the present invention in the order in which the device is fabricated.

FIG. 22 is a schematic diagram for describing reflection efficiencies of the light emitting diodes of the first and fourth embodiments of the present invention.

FIG. 23 is a diagram showing the dependency of a reflectance on the angle θ of incident light from a GaN film.

FIG. 24 is a graph showing the result of comparison of the total flux outputs of the nitride semiconductor light emitting diodes of the first and fourth embodiments.

FIGS. 25(a)-25(e) are cross-sectional views showing a method for fabricating a nitride semiconductor light emitting diode according to a fifth embodiment of the present invention in the order in which the device is fabricated, and showing a second method for fabricating the nitride semiconductor light emitting diode of the fourth embodiment in the order in which the device is fabricated.

FIG. 26 is a cross-sectional view showing a structure of a light emitting diode according to Conventional Example 1.

FIG. 27 is a cross-sectional view showing a structure of a light emitting diode according to Conventional Example 2.

### DESCRIPTION OF EMBODIMENTS

The present invention will be described hereinafter with reference to the drawings and the detailed description. Changes and additions can be made to the techniques disclosed herein by those skilled in the art after understanding preferred examples of the present invention, without departing the spirit and scope of the present invention. One of a plurality of embodiments described below may be combined with another while remaining within the scope of the present invention.

### First Embodiment

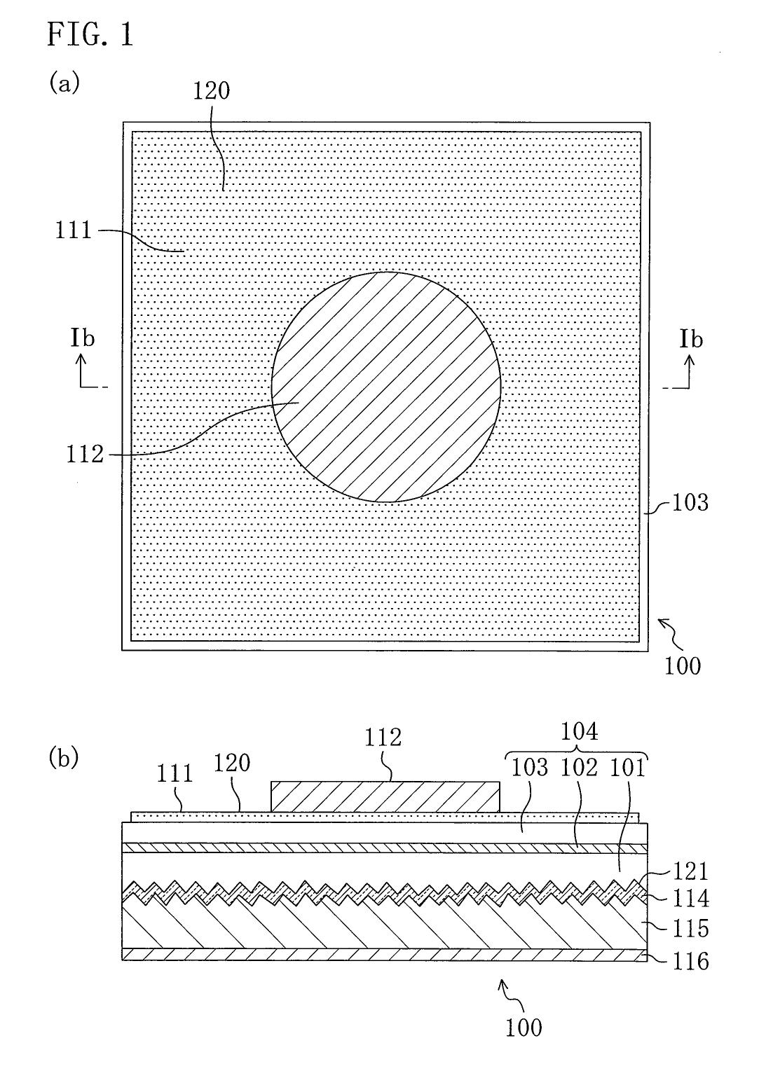

A nitride semiconductor light emitting diode according to a first embodiment of the present invention will be described with reference to FIGS. 1-12.

—Structure of Nitride Semiconductor Light Emitting Diode of First Embodiment of the Invention—

FIG. 1(a) is a top view of the nitride semiconductor light emitting diode 100 of this embodiment. FIG. 1(b) is a cross-sectional view of the nitride semiconductor light emitting diode 100, taken along line 1b-1b of FIG. 1(a).

As shown in FIG. 1, for example, the nitride semiconductor light emitting diode 100 of this embodiment includes a nitride semiconductor layer 104 including an n-type GaN layer 101 having a thickness of 2 μm doped with Si having a concentration of 5×10¹⁸ cm⁻³, a light emission layer 102 having a multiple quantum well structure in which a plurality of InₓGa₁₋ₓN well layers and a plurality of GaN barrier layers are alternately formed, and a p-type GaN layer 103 having a thickness of 0.5 μm doped with Mg having a concentration of 5×10¹⁸ cm⁻³, which are stacked in this stated order. A transparent electrode 111 having a thickness of 0.2 μm made of, for example, indium tin oxide (ITO), ZnO doped with Ga, or the like, which transmits light emitted from the light emission layer 102 is formed on an upper surface of the p-type GaN layer 103 to constitute a light emitting surface 120 of the light emitting diode. A p-electrode 112 is formed on a portion of an upper surface of the transparent electrode 111. Moreover, a bonding layer 114 made of Al having a thickness of 0.2 μm is provided on a lower surface of the n-type GaN layer 101 to form a reflective surface 121. A support substrate 115 having a thickness of, for example, 50 μm made of a conductive material including Cu, Au, or the like, and a backside electrode 116 are provided below the bonding layer 114. The p-electrode 112 and the backside electrode 116 are formed of a multilayer film, such as Ti/Al/Ti/Au, Cr/Pt/Au, or the like.

In the aforementioned structure, an uneven topography having a plurality of sloped surfaces is provided in a surface contacting the bonding layer 114 of the n-type GaN layer 101, and the bonding layer 114 is formed, contacting the uneven topography. As a result, the reflective surface 121 formed by the bonding layer 114 has a structure with an uneven surface. Here, the uneven surface may be, for example, a crystal face of a nitride semiconductor. Specifically, for example, a pyramid-shaped uneven surface having a {10-1-1} plane which is a kind of semipolar plane of a nitride semiconductor can be formed in a surface of the n-type GaN layer 101 by a wet etching method using an aqueous KOH solution in combination with irradiation with ultraviolet light, and can be used as an uneven reflective surface. Note that the semipolar plane means a plane which is sloped with respect to the c-plane, i.e., the (0001) plane as described above. The braces { } indicate a group of planes having the same relative relationship with respect to the coordinate axes of crystal. The {1-10-1} planes include six equivalent planes, i.e., the (1-10-1), (10-1-1), (01-1-1), (−110-1), (−101-1), and (0-11-1) planes. On the {1-10-1} planes, a topmost surface terminated with Group III atoms, such as Ga atoms or the like, is formed. The Group III atom in the topmost surface does not have a bond with a nitrogen atom, and therefore, is a negative ion having one more electron than it has protons, and therefore, the n-type carrier concentration effectively increases in the topmost surface, so that the contact resistance between the topmost surface and the bonding layer can be reduced. Therefore, the increase in the operating voltage can be reduced or prevented.

Although Al is used as a material constituting the bonding layer 114, this embodiment is not limited to this. In addition to Al, other metals can be used if the metal is made of atoms of the same Group III to which Ga atoms belong or an alloy containing Group III atoms. In this case, Group III atoms constituting the bonding layer, and Group III atoms constituting the topmost surface of the n-type GaN layer, such as Ga or the like, easily react with each other, so that surface reconstruction occurs. Therefore, a chemical bonding strength between the nitride semiconductor layer and the bonding layer increases. As a result, the adhesiveness between the n-type GaN layer and the bonding layer is significantly improved. Note that, if the wavelength of light emitted from the light emission layer 102 is 350-550 nm, it is most preferable to use Al, which has a high reflectance with respect to light having a wavelength within that range.

Although the p-electrode 112 and the backside electrode 116 are formed of a multilayer film, such as Ti/Al/Ti/Au, Cr/Pt/Au, or the like, the present invention is not limited to this. The p-electrode 112 and the backside electrode 116 may be formed of an alloy or a multilayer film including at least one selected from the group consisting of Ti, Pd, Pt, Al, Ni, and Au.

—Method for Fabricating Nitride Semiconductor Light Emitting Diode of First Embodiment of the Invention—

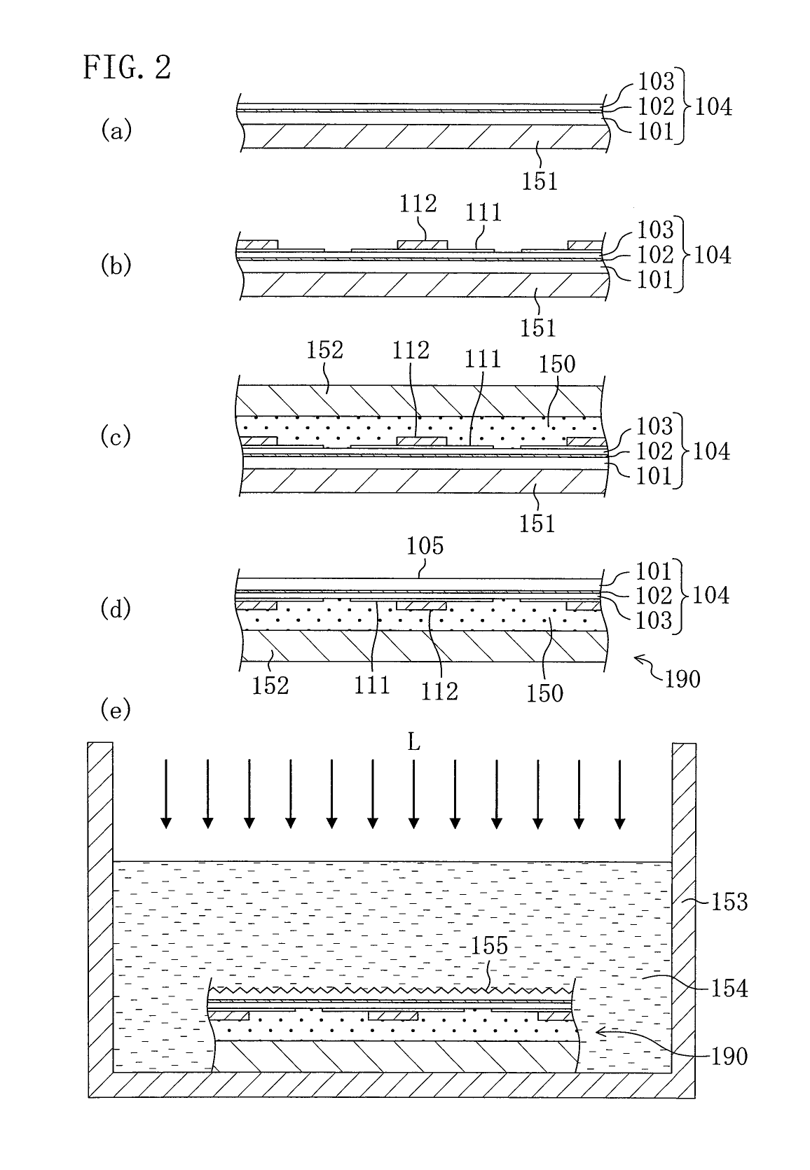

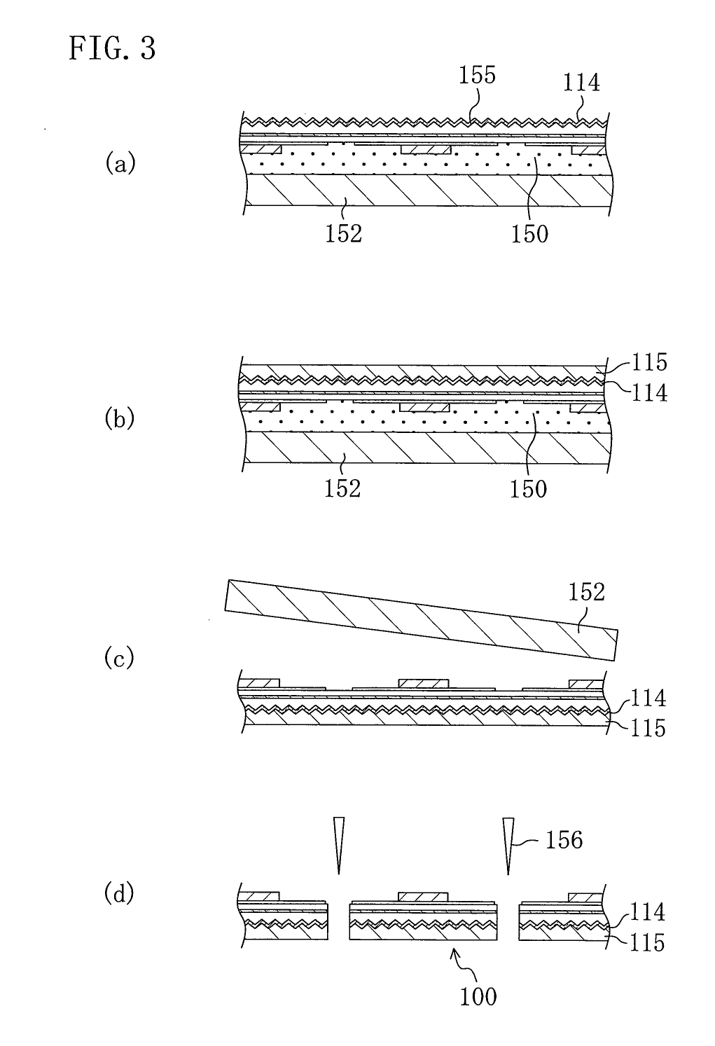

A method for fabricating the nitride semiconductor light emitting diode of this embodiment will be described with reference to FIGS. 2(a)-2(e) and 3(a)-3(d).

Initially, as shown in FIG. 2(a), the nitride semiconductor layer 104 including the n-type GaN layer 101, the light emission layer 102 having a multiple quantum well structure in which a plurality of InₓGa₁₋ₓN well layers and a plurality of GaN barrier layers are alternately formed, and the p-type GaN layer 103, which are successively stacked, is formed on a primary surface of a first substrate 151, such as a Si substrate having a <111> surface orientation, a sapphire substrate having a <0001> surface orientation, a 6H—SiC substrate having a <0001> surface orientation, or the like, by epitaxial growth using a metal organic chemical vapor deposition (MOCVD) method, with a buffer layer (not shown), such as an AlN layer, a low-temperature-grown GaN layer, or the like, being interposed between the nitride semiconductor layer 104 and the first substrate 151.

Next, as shown in FIG. 2(b), the transparent electrode 111 made of, for example, ITO is selectively formed on a portion of the upper surface of the p-type GaN layer 103 using a vacuum deposition method and a photolithography method, and thereafter, an annealing treatment is performed in an oxygen atmosphere. Thereafter, the p-electrode 112 is selectively formed on a portion of the upper surface of the transparent electrode 111 using a vacuum deposition method and a photolithography method.

Next, as shown in FIG. 2(c), an adhesive layer 150 is applied to cover a surface of the nitride semiconductor layer 104 on which the transparent electrode 111 is formed, and a second substrate 152 is caused to adhere to the nitride semiconductor layer 104 via the adhesive layer 150. Examples of an adhesive constituting the adhesive layer 150 include silicone-based resins, waxes, or the like, which are resistant to a strong alkaline solution, such as potassium hydroxide (KOH) or the like. Silicone-based resins or waxes can be removed using a predetermined remover or by heating.

Next, as shown in FIG. 2(d), the first substrate 151 is removed to form an exposure surface 105 which exposes the n-type GaN layer 101. If the first substrate 151 is a silicon substrate, the first substrate 151 can be removed by wet etching using, for example, a mixture of hydrofluoric acid and nitric acid. Alternatively, if the first substrate 151 is a sapphire substrate, the first substrate 151 can be removed by a laser liftoff method.

Next, as shown in FIG. 2(e), the exposure surface 105 of the n-type GaN layer 101 is subjected to wet etching using a photoelectrochemical (PEC) etching method in which an aqueous KOH solution is used in combination with irradiation with ultraviolet light. Specifically, the substrate 190 formed in the step of FIG. 2(d) is immersed in a vessel 153 holding an aqueous potassium hydroxide (KOH) solution 154, and is then subjected to wet etching while being irradiated with ultraviolet light L. In this case, for example, the concentration of the aqueous KOH solution is 45%, the temperature is room temperature, and the irradiation intensity of the ultraviolet light L is 10 mW/cm².

PEC etching, when applied to nitride semiconductors, has anisotropy depending on a plane orientation. Therefore, {1-10-1} planes sloped by a predetermined angle with respect to the (0001) plane are formed in the etched surface of the n-type GaN layer 101. As a result, an uneven surface 155 having sloped surfaces formed by the {1-10-1} planes is formed.

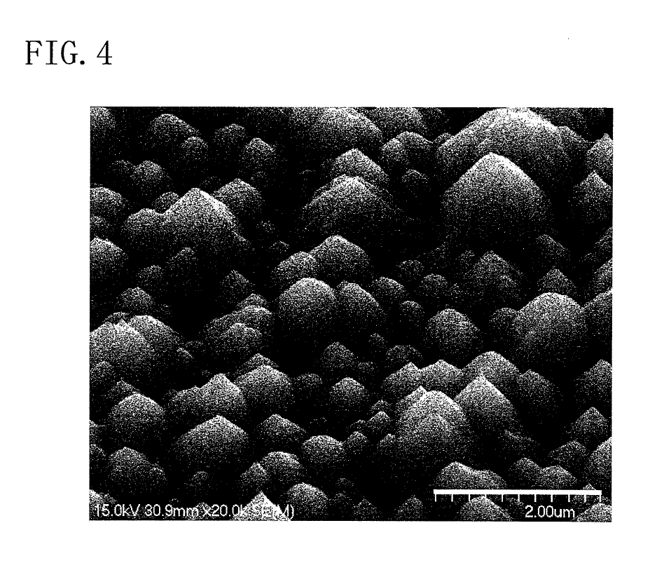

Here, FIG. 4 shows a high-resolution electron micrograph of the n-type GaN layer surface after formation of an uneven topography by PEC etching.

As can be seen from FIG. 4, a pyramid-shaped uneven surface is formed by PEC etching. The pyramid-shaped uneven surface is a semipolar plane having a {1-10-1} plane orientation.

Next, as shown in FIG. 3(a), the bonding layer 114 is formed on the uneven surface 155 by depositing a metal made of III atoms or an alloy thereof using an electron beam deposition method.

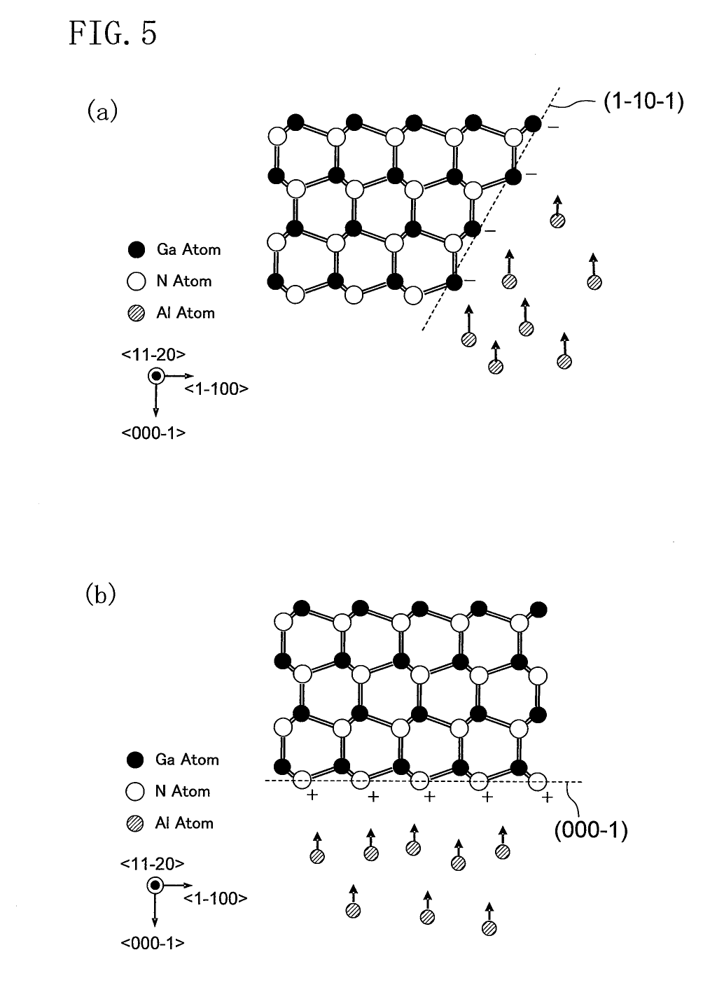

Here, an advantage of the formation of a metal made of Group III atoms on the uneven surface 155 will be described with reference to FIGS. 5(a) and 5(b). FIG. 5(a) shows an atomic arrangement of the topmost surface of the n-type GaN layer of this embodiment. As shown in FIG. 5(a), in this embodiment, a semipolar plane having, for example, the (1-10-1) plane orientation terminated with Ga atoms which are Group III atoms is formed in the topmost surface of the n-type GaN layer. In this case, Ga atoms in the termination portion do not have a bond with N atoms, and therefore, are a negative ion having one more electron than it has protons, and therefore, the n-type carrier concentration effectively increases in the topmost surface. As a result, by forming a bonding layer made of a metal, such as Al or the like, on such an uneven surface having a semipolar plane, the contact resistance between the n-type GaN layer and the bonding layer is reduced, whereby the increase in the operating voltage of the nitride semiconductor light emitting diode is reduced or prevented.

On the other hand, for comparison, FIG. 5(b) shows an atomic arrangement of the topmost surface of the n-type GaN layer when an uneven topography is not formed in the surface of the n-type GaN layer. This structure in which an uneven topography is not formed in the surface of the n-type GaN layer corresponds to that of Conventional Example 1. In this case, a (000-1) plane terminated with N atoms is formed in the topmost surface of the n-type GaN layer. In this case, N atoms in the termination portion do not have a bond with Ga atoms, and therefore, are a positive ion which has a dangling bond with an unpaired electron, and effectively function as positive holes. Therefore, the n-type carrier concentration decreases in the topmost surface. As a result, if a metal such as Al or the like is formed on the (000-1) plane, the contact resistance increases, and therefore, the operating voltage of the nitride semiconductor light emitting diode increases.

As described above, by forming a semipolar plane in the topmost surface of the n-type GaN layer and forming a metal on the topmost surface, the increase in the operating voltage of the light emitting diode can be reduced or prevented.

Moreover, when the material constituting the bonding layer 114 is a metal made of Group III atoms, Group III atoms constituting the bonding layer 114 easily react with Group III atoms (Ga, etc.) constituting the topmost surface of the n-type GaN layer, so that surface reconstruction occurs, and therefore, the chemical bonding strength between the nitride semiconductor layer and the bonding layer 114 increases. As a result, the adhesiveness between the n-type GaN layer and the bonding layer is significantly improved.

Although Al is used as the Group III atom which is a material constituting the bonding layer 114, the present invention is not limited to this. In particular, by using Group III atoms belonging to the same group as that of Ga, an advantage similar to that of Al described above is obtained. Although an electron beam deposition method is used to form the material of the bonding layer 114 into an uneven surface, the present invention is not limited to this. For example, other deposition techniques such as a resistance heating deposition method and the like, a sputtering technique, and the like can be used.

Next, as shown in FIG. 3(b), the support substrate 115 made of a conductive material is formed, contacting the upper surface of the bonding layer 114. In this case, materials having excellent heat dissipation ability are preferable as the material constituting the support substrate 115. For example, the support substrate 115 is preferably formed by an electrolytic or nonelectrolytic plating method using a metal material, such as Ni, Cu, Au, or the like. Among them, a metal film of Cu formed using an electrolytic plating method is particularly preferably used to form the support substrate 115 with low cost.

Next, as shown in FIG. 3(c), the adhesive layer 150 is removed using a remover liquid for the adhesive layer 150, thereby separating the second substrate 152.

Next, as shown in FIG. 3(d), chip separation is performed by dicing using a blade 156 to form the nitride semiconductor light emitting diode 100.

—Operation and Advantages of Nitride Semiconductor Light Emitting Diode of this Embodiment—

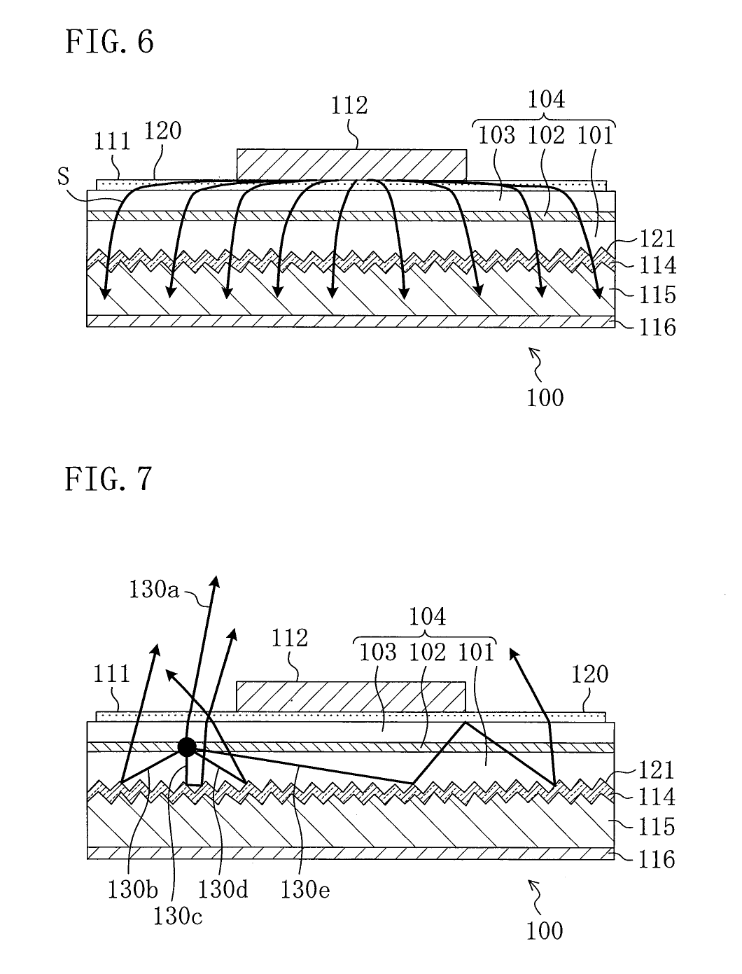

Operation and advantages of the nitride semiconductor light emitting diode 100 of this embodiment will be described with reference to FIGS. 6 and 7.

FIG. 6 is a diagram schematically showing the flow of a current in the nitride semiconductor light emitting diode 100 of this embodiment.

As shown in FIG. 6, a current is injected into the nitride semiconductor light emitting diode 100 of this embodiment via the p-electrode 112 and the backside electrode 116. The current injected into the p-electrode 112 is expanded over an entire surface of the nitride semiconductor light emitting diode 100 by the transparent electrode 111, and is then passed through the p-type GaN layer 103 and injected into the light emission layer 102. In this case, the current injected into the light emission layer 102 is converted into light, depending on the amount of the current, i.e., light is generated, and the generated light is emitted in all directions in the nitride semiconductor layer 104.

FIG. 7 shows trajectories of the generated light in the nitride semiconductor light emitting diode 100 of this embodiment.

As shown in FIG. 7, of the light emitted from some point in the light emission layer 102, light emitted toward the light emitting surface 120 (e.g., generated light 130a) is passed through the transparent electrode 111, and is emitted to the outside of the nitride semiconductor light emitting diode 100. On the other hand, light emitted toward the reflective surface 121 opposite to the light emitting surface 120 (e.g., generated light 130b, 130c, and 130d) undergoes diffuse reflection on the reflective surface 121 having the uneven surface and is directed to the light emitting surface, is passed through the transparent electrode 111, and is emitted to the outside of the nitride semiconductor light emitting diode 100. Moreover, of the light traveling toward the reflective surface 121, light emitted in a horizontal and oblique direction (e.g., generated light 130e) is reflected toward the light emitting surface while the light is not absorbed by the nitride semiconductor layer 104, and is emitted to the outside of the nitride semiconductor light emitting diode 100. Thus, the structure of the nitride semiconductor light emitting diode of this embodiment has an improved light extraction efficiency.

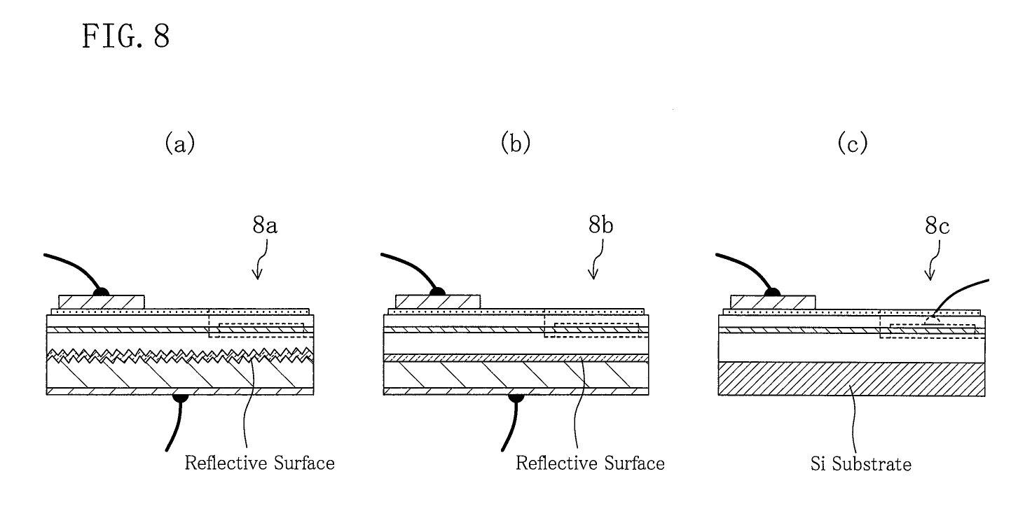

Next, results of an experimental demonstration of the aforementioned nitride semiconductor light emitting diode in terms of the improvement in the light extraction efficiency, the improvement in the adhesiveness, and the reduction in the operating voltage, will be described with reference to FIGS. 8-11.

FIGS. 8(a)-8(c) show structures of nitride semiconductor light emitting diodes which were fabricated for the demonstration. FIG. 8(a) shows a structure of the nitride semiconductor light emitting diode of this embodiment. FIG. 8(b) shows a structure of a nitride semiconductor light emitting diode fabricated by the aforementioned fabrication method in which an uneven topography was not formed (the structure of Conventional Example 1). FIG. 8(c) shows a structure of a nitride semiconductor light emitting diode (without a reflective surface) in which a single-sided electrode structure is formed, and a reflective surface closer to the back surface is not formed.

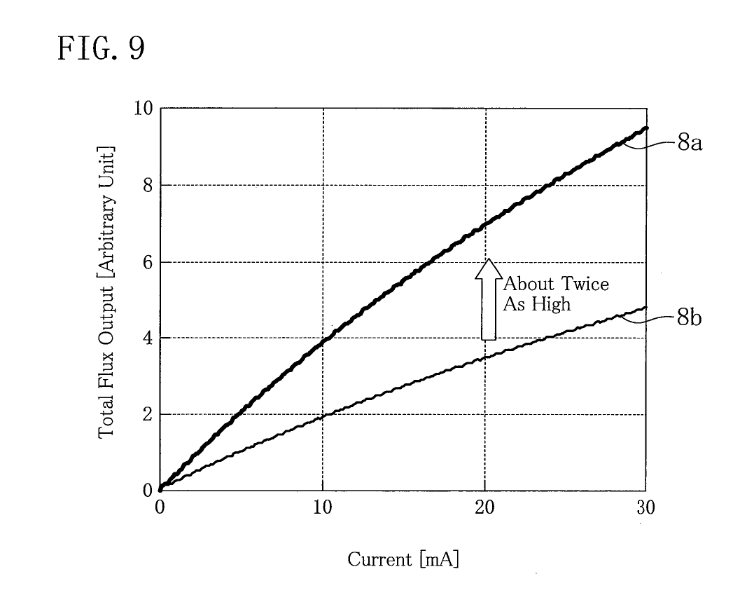

Firstly, FIG. 9 shows a diagram in which total flux output-current characteristics of the nitride semiconductor light emitting diodes 8a and 8b of FIGS. 8(a) and 8(b) are plotted.

As can be seen from FIG. 9, the total flux output (8a of FIG. 9) of the nitride semiconductor light emitting diode of this embodiment is improved by a factor of about two compared to the total flux output (8b of FIG. 9) of the nitride semiconductor light emitting diode of Conventional Example 1. Thus, the light extraction efficiency is improved by using the structure of the present invention.

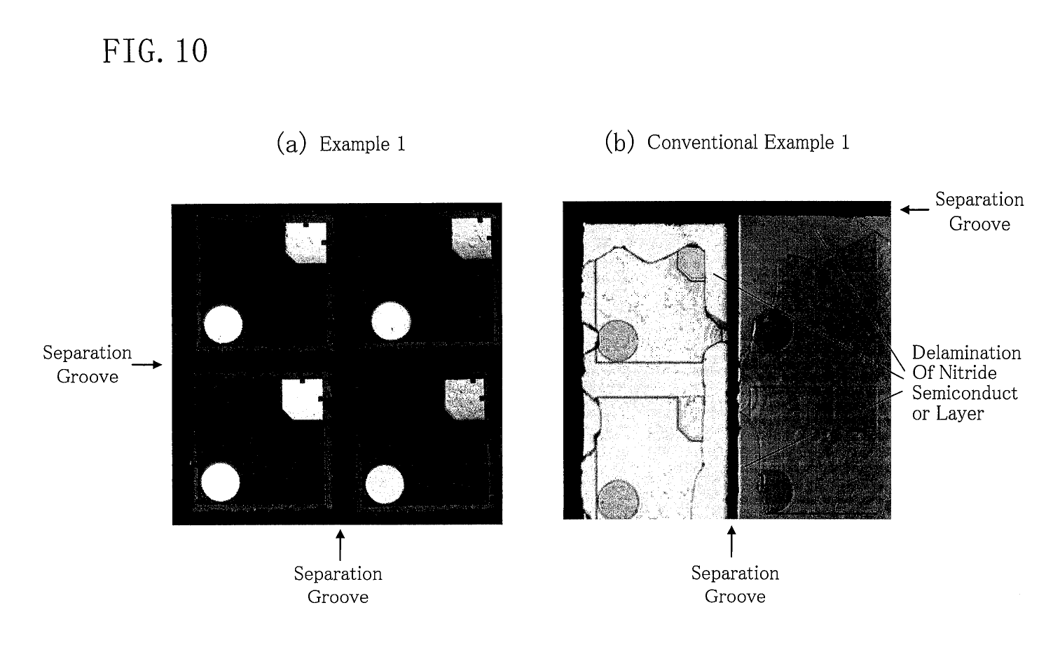

Next, the achievement of the improvement in the adhesiveness between the bonding layer and the nitride semiconductor layer in this embodiment will be described with reference to FIG. 10.

FIG. 10 is a photograph of states of the nitride semiconductor light emitting diodes of FIGS. 8(a) and 8(b) after chip separation by dicing using a blade, taken from the light emitting surface side using an optical microscope.

As can be seen from FIG. 10, in the nitride semiconductor light emitting diode of this embodiment (FIG. 10(a)), the nitride semiconductor layer was not delaminated by chip separation. However, in the nitride semiconductor light emitting diode of Conventional Example 1 (FIG. 10(b)), a portion in which the nitride semiconductor layer was delaminated was found in the vicinity of a portion in which a separation groove was formed by chip separation. According to these results, it is understood that, by forming an uneven surface including a {1-10-1} plane on the reflective surface of the nitride semiconductor light emitting diode, the adhesiveness between the nitride semiconductor layer and the bonding layer can be sufficiently increased.

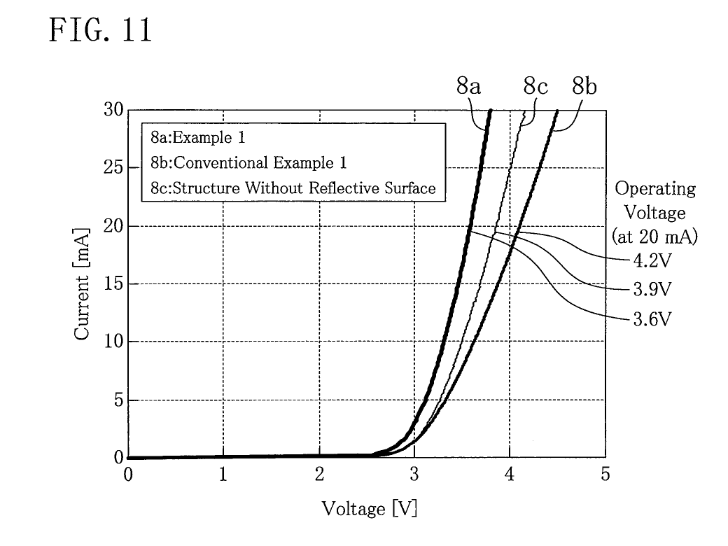

Next, the reduction or prevention of the increase in the operating voltage by the structure of this embodiment will be described with reference to FIG. 11.

FIG. 11 is a diagram in which current-voltage characteristics of the nitride semiconductor light emitting diodes indicated by 8a-8c of FIG. 8 are plotted. Here, in Conventional Example 1 indicated by 8b of FIG. 8, as shown in FIG. 10(b), the wafer was not able to be diced into individual chips, because of delamination due to the dicing, and therefore, the wafer was diced into a size which was not affected by delamination.

As can be seen from FIG. 11, the operating voltage (8b in FIG. 11) of the nitride semiconductor light emitting diode of Conventional Example 1 is higher than the operating voltage (8c in FIG. 11) of the nitride semiconductor light emitting diode without a reflective surface. On the other hand, the operating voltage (8a of FIG. 11) of the nitride semiconductor light emitting diode of this embodiment is lower than the operating voltage (8c in FIG. 11) of the nitride semiconductor light emitting diode without a reflective surface. Specifically, when the injected current is 20 mA, the operating voltage of Conventional Example 1 indicated by 8b of FIG. 11 is 4.2 V, which is higher by 0.3 V than that of the nitride semiconductor light emitting diode without a reflective surface indicated by 8c of FIG. 11. In contrast to this, the operating voltage of this embodiment indicated by 8a of FIG. 11 is 3.6 V, which is lower by 0.3 V than that of the nitride semiconductor light emitting diode without a reflective surface indicated by 8c of FIG. 11. Thus, the structure of the nitride semiconductor light emitting diode of this embodiment not only can improve the light extraction efficiency, but also can reduce or prevent the increase in the operating voltage.

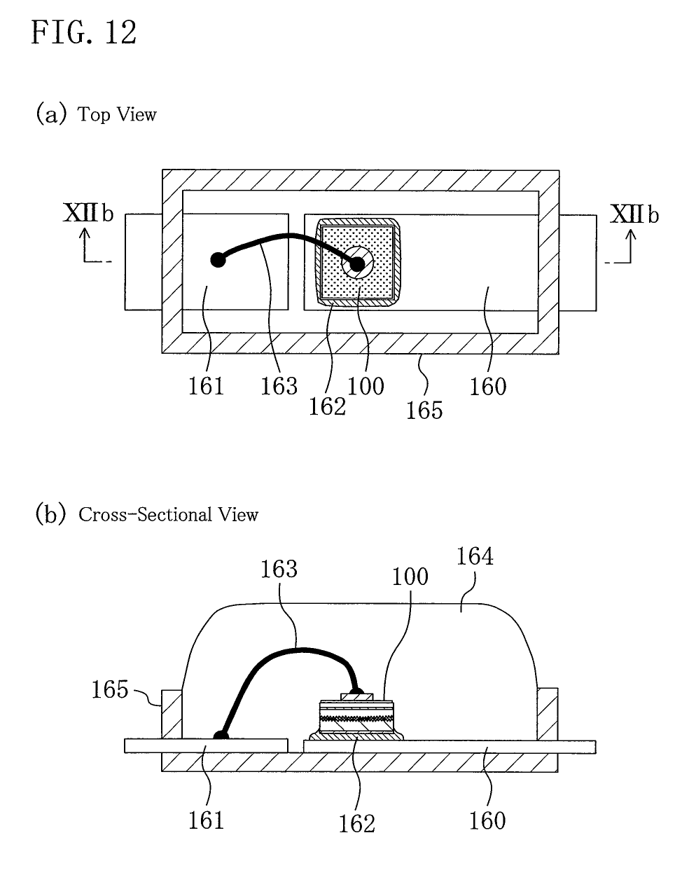

Because of the structure of this embodiment, the nitride semiconductor light emitting diode of this embodiment and conventional nitride semiconductor light emitting diodes can employ a common package structure. Next, this feature will be described with reference to FIGS. 12(a) and 12(b).

FIG. 12(a) is a top view of an example package structure when the nitride semiconductor light emitting diode 100 of this embodiment is used. FIG. 12(b) is a cross-sectional view taken along line XIIb-XIIb of FIG. 12(a).

The nitride semiconductor light emitting diode 100 of this embodiment is a p-side up electrode type light emitting diode in which a p-electrode is formed on the light emitting surface while an n-electrode is formed on the back surface of the substrate. Therefore, as shown in FIGS. 12(a) and 12(b), the package structure is as follows: the back surface of the substrate is coupled and fixed to an n-electrode wiring portion 160 of a lead frame using a conductive resin adhesive 162, such as a silver paste or the like, and the p-electrode is coupled to a p-electrode wiring portion 161 of the lead frame using a Au wire 163; and thereafter, the resultant structure is covered with a resin 164, such as an epoxy or the like, which is then molded into a lamp shape, and is then cured at high temperature, so that packaging is completed.

Thus, the nitride semiconductor light emitting diode 100 of this embodiment can be packaged using the same package structure as that of conventional nitride semiconductor light emitting diodes employing a conductive SiC substrate. As a result, the increase in the cost of the nitride semiconductor light emitting diode can be reduced or prevented.

### Second Embodiment

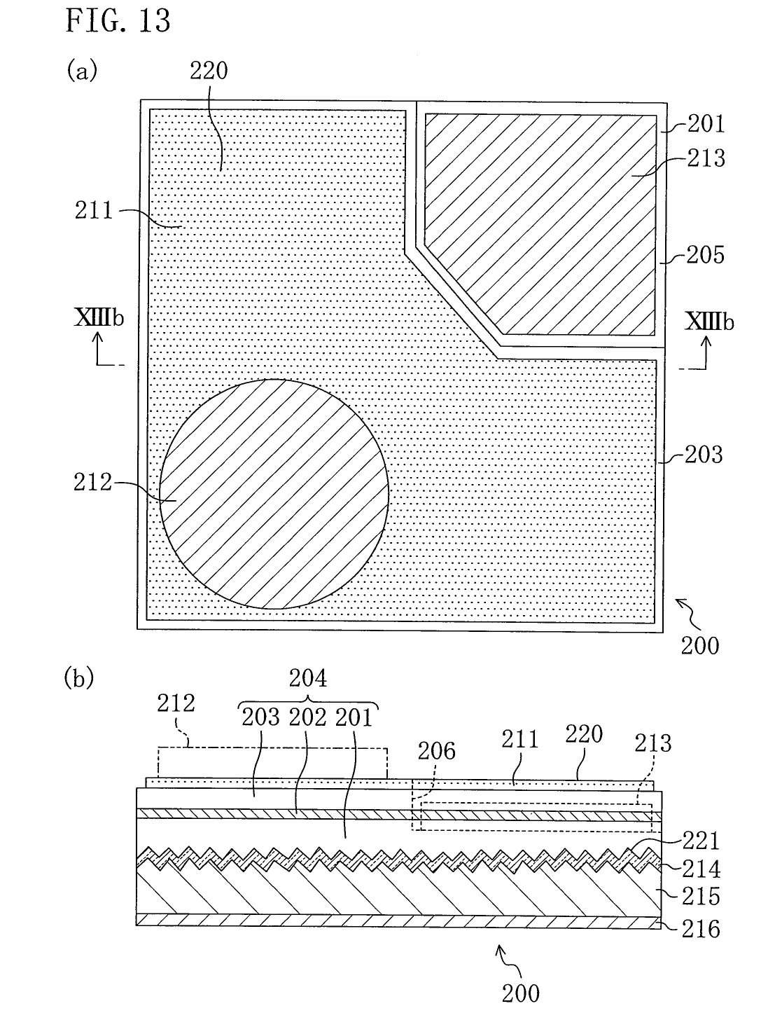

Next, a nitride semiconductor light emitting diode according to a second embodiment of the present invention will be described with reference to FIGS. 13-16.

FIG. 13(a) is a top view of the nitride semiconductor light emitting diode 200 of this embodiment. FIG. 13(b) is a cross-sectional view of the nitride semiconductor light emitting diode 200, taken along line XIIIb-XIIIb of FIG. 13(a).

As shown in FIGS. 13(a) and 13(b), the nitride semiconductor light emitting diode 200 of this embodiment is different from the nitride semiconductor light emitting diode of the first embodiment in that the nitride semiconductor light emitting diode 200 of this embodiment is of the single-sided electrode type, in which both of the p-electrode and the n-electrode are formed on the light emitting surface. The other portions of the nitride semiconductor light emitting diode 200 of this embodiment are similar to those of the nitride semiconductor light emitting diode of the first embodiment and will not be described.

—Method for Fabricating Nitride Semiconductor Light Emitting Diode of this Embodiment—

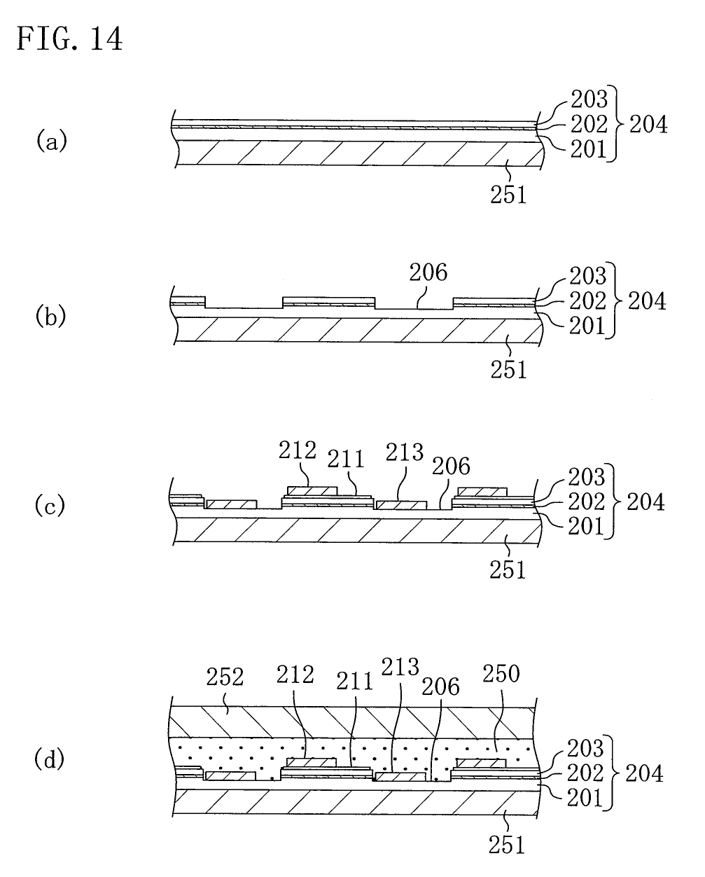

A method for fabricating the nitride semiconductor light emitting diode of this embodiment will be described with reference to FIGS. 14(a)-14(d).

Initially, as shown in FIG. 14(a), a nitride semiconductor layer 204 including an n-type GaN layer 201, a light emission layer 202 having a multiple quantum well structure in which a plurality of InₓGa₁₋ₓN well layers and a plurality of GaN barrier layers are alternately formed, and a p-type GaN layer 203, which are successively stacked, is formed on a primary surface of a first substrate 251, such as a Si substrate having a <111> surface orientation, a sapphire substrate having a <0001> surface orientation, a 6H—SiC substrate having a <0001> surface orientation, or the like, by epitaxial growth using a metal organic chemical vapor deposition (MOCVD) method, with a buffer layer (not shown), such as an AlN layer, a low-temperature-grown GaN layer, or the like, being interposed between the nitride semiconductor layer 204 and the first substrate 251.

Next, as shown in FIG. 14(b), a portion of the nitride semiconductor layer 204 is removed using a photolithography method and a dry etching method to form an opening 206 which exposes a portion of the n-type GaN layer 201.

Next, as shown in FIG. 14(c), a transparent electrode 211 made of, for example, ITO is selectively formed on a portion of an upper surface of the p-type GaN layer 203 using a vacuum deposition method and photolithography, and thereafter, an annealing treatment is performed in an oxygen atmosphere. Thereafter, a p-electrode 212 is selectively formed on a portion of an upper surface of the transparent electrode 211, while an n-electrode 213 is formed on an upper surface of the opening 206, using a vacuum deposition method and photolithography.

Next, as shown in FIG. 14(d), an adhesive layer 250 is applied to cover a surface of the nitride semiconductor layer 204 on which the transparent electrode 211 is formed, and a second substrate 252 is caused to adhere to the nitride semiconductor layer 204 via the adhesive layer 250.

The subsequent steps are similar to the steps of FIGS. 2(d) and 2(e) and 3(a)-3(d) of the method for fabricating the nitride semiconductor light emitting diode 100 of the first embodiment.

—Operation and Advantages of Nitride Semiconductor Light Emitting Diode of this Embodiment—

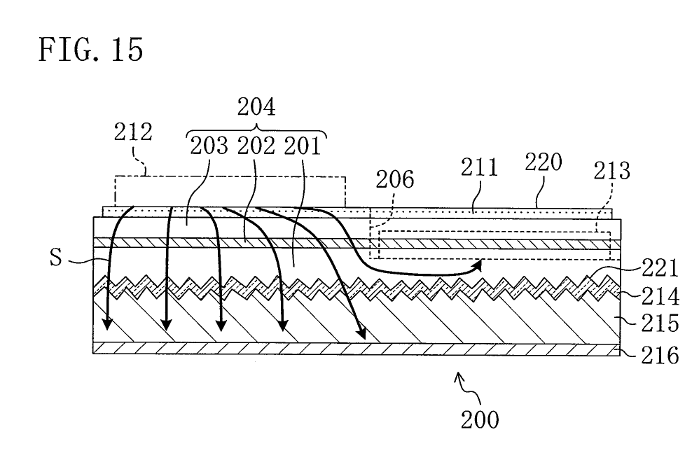

FIG. 15 is a diagram schematically showing the flow of a current in the nitride semiconductor light emitting diode 200 of this embodiment.

As shown in FIG. 15, in the nitride semiconductor light emitting diode 200 of this embodiment, there are two paths in which a current flows: a path from the p-electrode 212 to the n-electrode 213; and a path from the p-electrode 212 to a backside electrode 216. Specifically, a current injected into the p-electrode 212 is expanded over an entire surface of the light emitting diode by the transparent electrode 211. Thereafter, the current is passed through the p-type GaN layer 203 and a light emission layer 202 to flow into the n-type GaN layer 201. Thereafter, the current is passed in the two paths, i.e., one path from the n-type GaN layer 201 through a bonding layer 214 and a support substrate 215 to the backside electrode 216, and the other path which goes horizontally in the n-type GaN layer 201 and then to the n-electrode 213. By thus providing two current paths in the back surface direction and in the horizontal direction with respect to the substrate, a current can be easily expanded in a plane of the light emitting diode, and the operating voltage can be reduced.

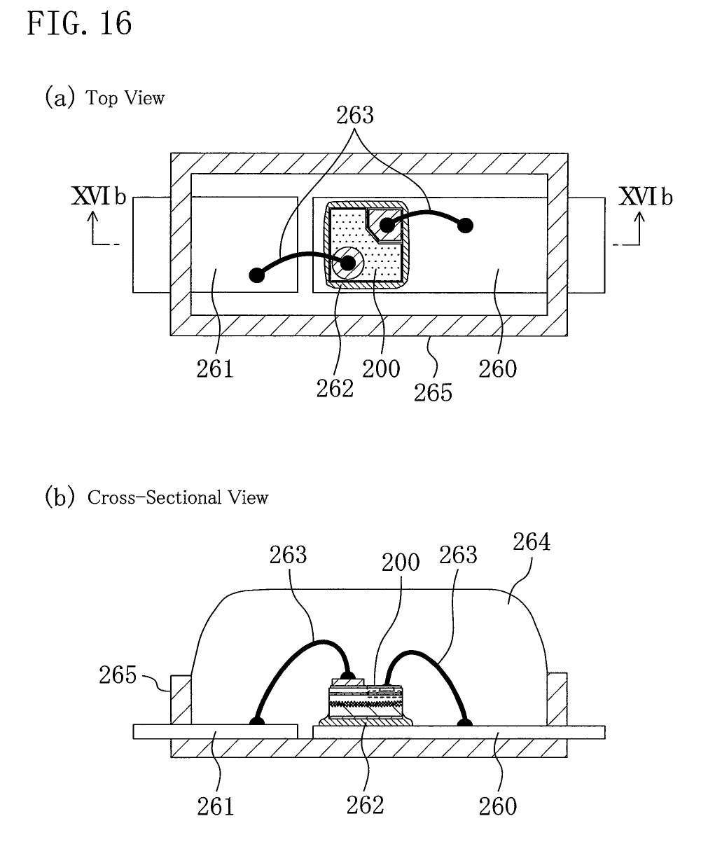

Because of the structure of this embodiment, the nitride semiconductor light emitting diode of this embodiment and conventional nitride semiconductor light emitting diodes can employ a common package structure. Next, this feature will be described with reference to FIGS. 16(a) and 16(b).

FIG. 16(a) is a top view of an example package structure when the nitride semiconductor light emitting diode 200 of this embodiment is used. FIG. 16(b) is a cross-sectional view taken along line XVb-XVb of FIG. 16(a).

As shown in FIGS. 16(a) and 16(b), the nitride semiconductor light emitting diode 200 of this embodiment is a single-sided electrode type light emitting diode in which a p-electrode and an n-electrode are both formed on the light emitting substrate. Therefore, as shown in FIGS. 16(a) and 16(b), the package structure is as follows: the back surface of the substrate is fixed to a lead frame using a resin adhesive 262, and both of the p-electrode and the n-electrode are coupled to a wiring portion of the lead frame using a Au wire 263; and thereafter, the resultant structure is covered with a resin 264, such as an epoxy or the like, which is then molded into a lamp shape, and is then cured at high temperature, so that packaging is completed.

Thus, the nitride semiconductor light emitting diode of this embodiment can be packaged using the same package structure as that of conventional light emitting diodes employing a sapphire substrate. As a result, the increase in the cost of the nitride semiconductor light emitting diode can be reduced or prevented.

### Third Embodiment

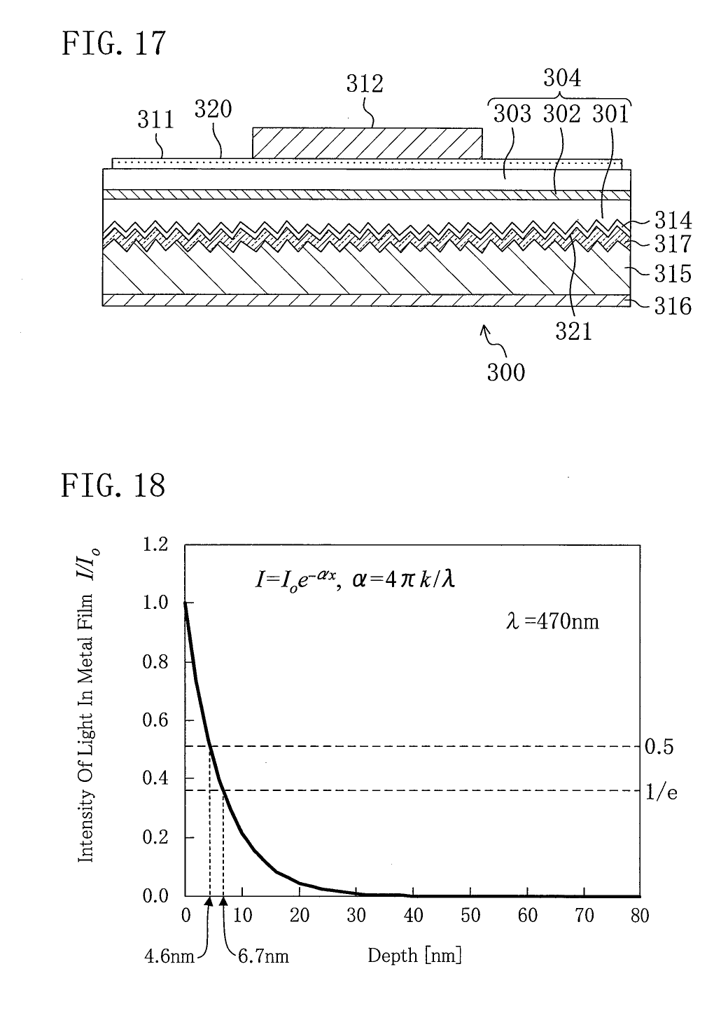

Next, a nitride semiconductor light emitting diode according to a third embodiment of the present invention will be described with reference to FIGS. 17 and 18.

FIG. 17 is a cross-sectional view of the nitride semiconductor light emitting diode 300 of this embodiment. Note that the top view of the nitride semiconductor light emitting diode of this embodiment is similar to that of the nitride semiconductor light emitting diode of the first embodiment of FIG. 1, and therefore, is not shown.

As shown in FIG. 17, the nitride semiconductor light emitting diode 300 of this embodiment is different from the nitride semiconductor light emitting diode 100 of the first embodiment in that a reflective layer 317 is provided between a bonding layer 314 and a support substrate 315, and the bonding layer 314 has a thickness which is smaller than or equal to a penetration depth with respect to light emitted from the light emission layer. The other portions of the nitride semiconductor light emitting diode 300 of this embodiment are similar to those of the nitride semiconductor light emitting diode of the first embodiment and will not be described.

—Method for Fabricating Nitride Semiconductor Light Emitting Diode of Third Embodiment of the Invention—

For example, the nitride semiconductor light emitting diode 300 of this embodiment of FIG. 17 includes a nitride semiconductor layer 304 including an n-type GaN layer 301, a light emission layer 302, and a p-type GaN layer 303, a transparent electrode 311 which is provided, contacting the p-type GaN layer 303, and transmits light emitted from the light emission layer 302, the bonding layer 314 which is provided, contacting the n-type GaN layer 301, the reflective layer 317 which is provided below the bonding layer 314, and the support substrate 315 which is provided below the reflective layer 317. A p-electrode 312 is formed on a portion of an upper surface of the transparent electrode 311, while a backside electrode 316 is formed on a lower surface of the support substrate 315. An uneven surface including a plurality of sloped surfaces is provided in a surface contacting the bonding layer 314 of the n-type GaN layer 301, and the bonding layer 314 and the reflective layer 317 are formed, contacting the uneven surface.

In this embodiment, the bonding layer 314 has a thickness which is smaller than or equal to a penetration depth with respect to light emitted from the light emission layer 302. As used herein, the penetration depth refers to a depth at which the intensity of light penetrating into a metal falls to 1/e. The penetration depth when Al, which is a Group III element, is used as a material constituting the bonding layer 314 will be specifically described hereinafter with reference to FIG. 18.

When light is incident on the surface of a metal, most of the light is totally reflected on the metal surface and a portion of the light penetrates into and is absorbed by the metal. The intensity of light penetrating from the metal surface into the metal inside is proportional to exp(−αx), where α is an absorption coefficient, and x is a depth from the metal surface. The absorption coefficient α is given by α=4πk/λ, where k is the imaginary part of the complex refractive index of the metal, and λ is the wavelength of the light. FIG. 18 shows a graph of the intensity of light penetrating from the surface of the metal Al into the inside of the metal, where the light wavelength is λ=470 nm.

As can be seen from FIG. 18, the light intensity falls to half when the depth is about 4.6 nm, and 1/e when the depth is 6.7 nm. Therefore, when the material constituting the bonding layer 314 is Al, if the thickness is 6.7 nm or less, the bonding layer 314 functions as a transparent thin metal film which transmits light.

Thus, in the structure of this embodiment in which the thickness of the bonding layer 314 is smaller than or equal to the penetration depth of light, light which is emitted from the light emission layer 302 toward the bonding layer 314 is transmitted through the bonding layer 314 to reach the surface of the reflective layer 317, and is reflected on the surface of the reflective layer 317. In this case, if the material constituting the reflective layer 317 is a metal which reflects light emitted from the light emission layer at a higher rate than that of the material constituting the bonding layer 314, the reflection efficiency can be improved compared to the first embodiment. Specifically, in the first embodiment, when Al is used as the material constituting the bonding layer 114, the reflectance of the GaN/Al interface is 84% with respect to perpendicularly incident light having a wavelength of 470 nm, i.e., 16% of the light is absorbed. On the other hand, when Al having a thickness of 6.7 nm or less is used as the bonding layer 314 as described in this embodiment, and Ag or an Ag alloy is used as the material constituting the reflective layer 317, a portion of the 16% light which is absorbed in the first embodiment can be reflected on the reflective layer 317, whereby the reflection efficiency can be improved compared to the first embodiment. We actually fabricated the nitride semiconductor light emitting diode of the third embodiment using Al having a thickness of 2 nm as the bonding layer 314 and Ag having a thickness of 0.2 μm as the reflective layer 317, and compared the nitride semiconductor light emitting diode of the third embodiment with the nitride semiconductor light emitting diode of the first embodiment, to find that the total flux output of the light emitting diode was successfully improved by 20%.

### Fourth Embodiment

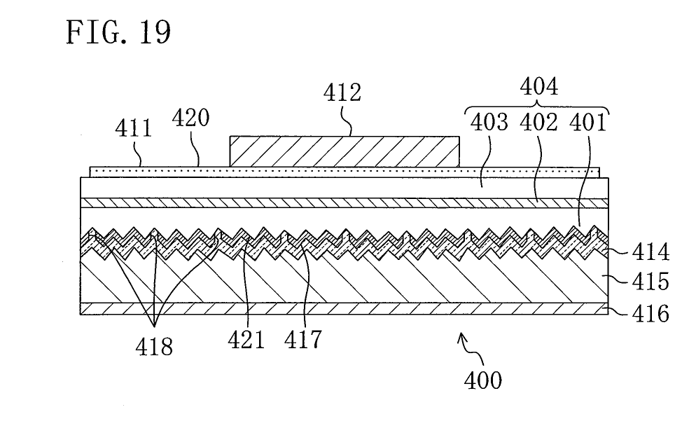

Next, a nitride semiconductor light emitting diode according to a fourth embodiment of the present invention will be described with reference to FIGS. 19-22.

FIG. 19 is a cross-sectional view of the nitride semiconductor light emitting diode 400 of this embodiment.

As shown in FIG. 19, the nitride semiconductor light emitting diode 400 of this embodiment is different from the nitride semiconductor light emitting diode 100 of the first embodiment in that a dielectric layer 417 having a plurality of openings 418 is provided between an n-type GaN layer 401 and a bonding layer 414, and the n-type GaN layer 401 contacts the bonding layer 414 via the openings 418. The other portions of the nitride semiconductor light emitting diode 400 of this embodiment are similar to those of the nitride semiconductor light emitting diode of the first embodiment and will not be described.

—Structure of Nitride Semiconductor Light Emitting Diode of Fourth Embodiment of the Invention—

For example, the nitride semiconductor light emitting diode 400 of this embodiment of FIG. 19 includes a nitride semiconductor layer 404 including the n-type GaN layer 401, a light emission layer 402, and a the p-type GaN layer 403, a transparent electrode 411 which is provided, contacting the p-type GaN layer 403, and transmits light emitted from the light emission layer 402, the bonding layer 414 which is provided below the n-type GaN layer 401, and a support substrate 415 which is provided, contacting a lower surface of the bonding layer 414. An uneven surface having a plurality of sloped surfaces is provided on a surface opposite to the light emission layer 402 of the n-type GaN layer 401.

In such a structure, the dielectric layer 417 having the openings 418 is provided between the n-type GaN layer 401 and the bonding layer 414 in this embodiment. As a material constituting the dielectric layer 417, a material having a small imaginary part of the complex refractive index, i.e., a small extinction coefficient is preferable for the purpose of reduction or prevention of light absorption, or a material which is used to easily form the dielectric layer 417 by electron beam deposition, plasma CVD, sputtering, or the like is preferable. Examples of such a material include SiO₂, TiO₂, MgF₂, CaF₂, SiₓN_{y}, AlₓO_{y}, LiF, and the like. Note that the openings 418 provided in the dielectric layer 417 are filled with the bonding layer 414 provided below the dielectric layer 417, and therefore, the n-type GaN layer 401 and the bonding layer 414 are connected via the openings 418, thereby allowing electrical conduction therebetween.

The dielectric layer 417 is formed of a multilayer dielectric film in which two materials having a large difference in refractive index, such as SiO₂ and TiO₂, or the like, selected from dielectric materials such as those described above, are alternately stacked (the multilayer dielectric film may include at least one selected material). Alternatively, the dielectric layer 417 is formed of a dielectric material having a refractive index sufficiently lower than that of nitride semiconductors for the wavelength of light emitted from the light emitting diode (e.g., a monolayer film made of one selected from the aforementioned materials). In the case of the latter, for example, when SiO₂ is used as the dielectric material, the refractive index is 1.46 with respect to blue light having a wavelength of 470 nm, and is therefore sufficiently lower than a refractive index of 2.5 of nitride semiconductors, and in addition, the openings 418 can be easily formed by wet etching. Thus, the latter is preferable.

—First Method for Fabricating Nitride Semiconductor Light Emitting Diode of this Embodiment—

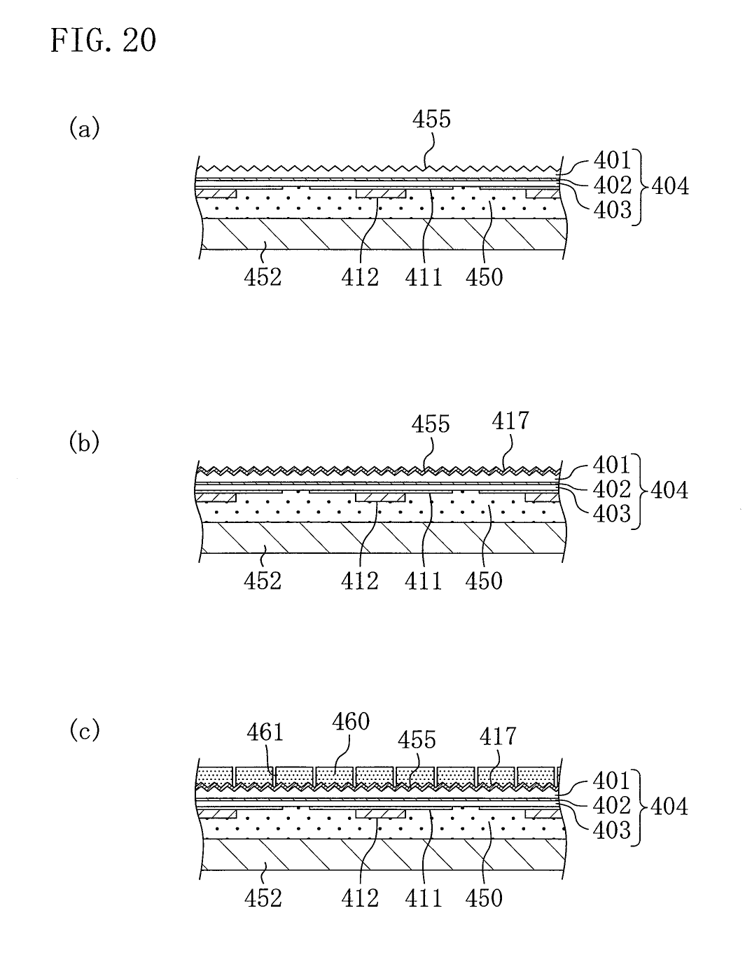

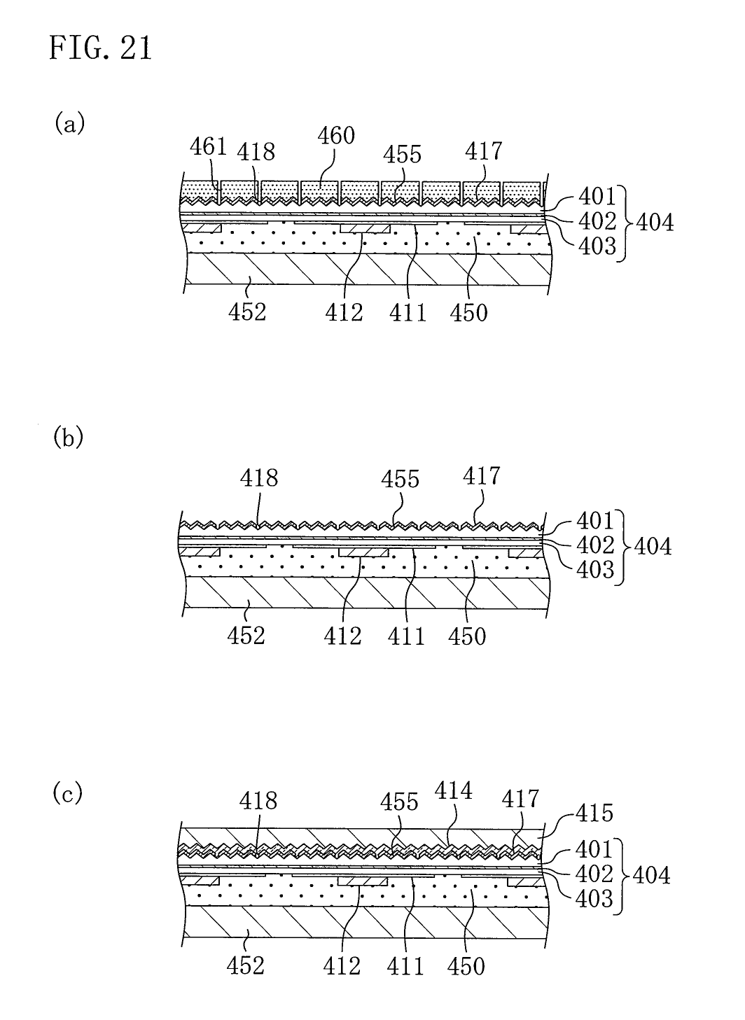

A first method for fabricating the nitride semiconductor light emitting diode of this embodiment will be described with reference to FIGS. 20(a)-20(c) and 21(a)-21(c).

Initially, as shown in FIG. 20(a), an uneven surface 455 is formed on the n-type GaN layer 401 by steps similar to those of FIGS. 2(a)-2(e) of the fabrication method of the first embodiment of the present invention, while the second substrate 452 adheres to the nitride semiconductor layer 404 via the adhesive layer 450.

Next, as shown in FIG. 20(b), the dielectric layer 417 is formed on the uneven surface 455. Specifically, as the dielectric layer 417, for example, a monolayer film made of SiO₂ or a multilayer dielectric film in which a SiO₂ film and a TiO₂ film are alternately stacked, is formed by an electron beam deposition method or the like.

Next, as shown in FIG. 20(c), after a resist layer 460 is formed, resist openings 461 are formed in the resist layer 460 by a photolithography method.

Next, as shown in FIG. 21(a), the openings 418 are formed in the dielectric layer 417 using the resist openings 461. In this case, when the dielectric layer 417 is a monolayer film made of, for example, a SiO₂ film, the openings 418 can be provided by wet etching using hydrofluoric acid. When the dielectric layer 417 is a multilayer dielectric film in which, for example, a SiO₂ film and a TiO₂ film are alternately stacked, the openings 418 can be provided by dry etching using fluorine-based gas.

Next, as shown in FIG. 21(b), the resist layer 460 in which the resist openings 461 are provided is removed to expose the dielectric layer 417.

Next, as shown in FIG. 21(c), after a metal made of III atoms such as Al or the like or an alloy thereof is deposited on the dielectric layer 417 to form the bonding layer 414, the support substrate 415 made of a conductive material is formed, contacting an upper surface of the bonding layer 414. Materials having excellent heat dissipation ability are preferable as the material constituting the support substrate 415. In particular, a metal film of Cu formed using an electrolytic plating method is preferably used to form the support substrate 415 with low cost.

The subsequent steps are similar to those of FIGS. 3(c) and 3(d) of the method of fabricating the nitride semiconductor light emitting diode 100 of the first embodiment.

—Operation and Advantages of Nitride Semiconductor Light Emitting Diode of this Embodiment—

In the structure of this embodiment, a portion of light emitted from the light emission layer 402 toward the substrate is reflected on a surface of the dielectric layer 417, and light which is transmitted through the dielectric layer 417 is also reflected on the bonding layer 414 provided on a lower surface of the dielectric layer 417. Therefore, in the structure of this embodiment, the reflection efficiency can be improved compared to the first embodiment.

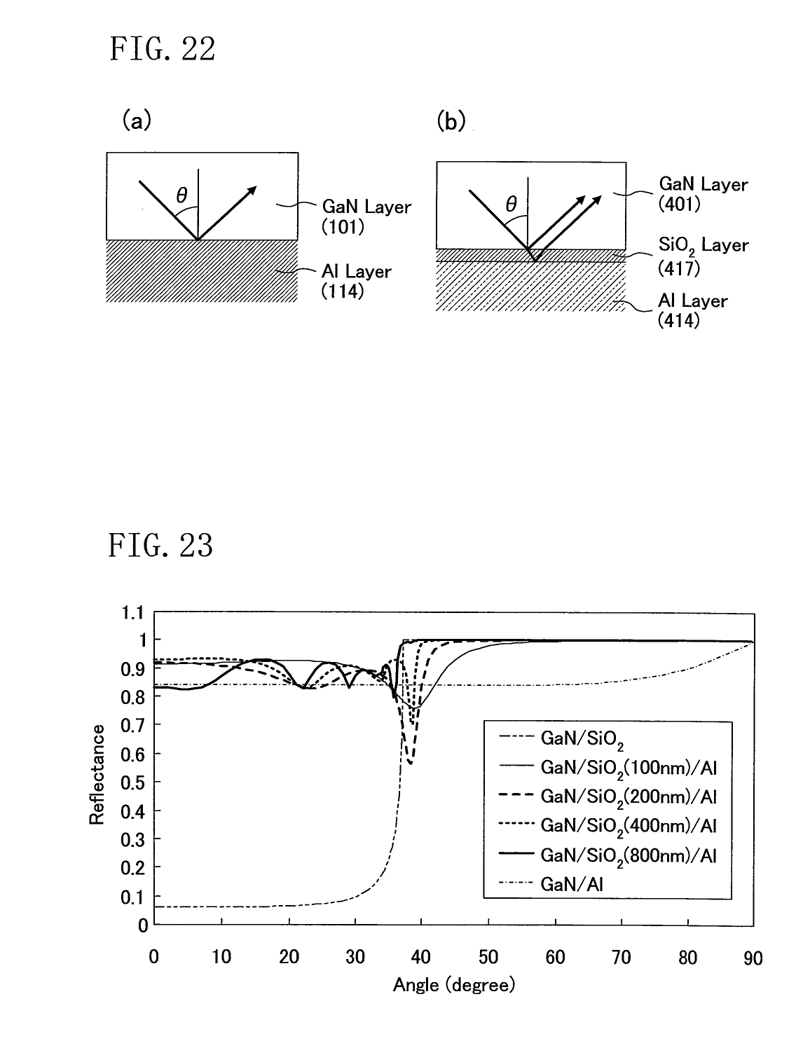

The results of demonstration of the improvement in the reflection efficiency of the nitride semiconductor light emitting diode of this embodiment by calculation and experimentation will be described with reference to Table 1 and FIGS. 22-24.

Table 1 below shows the complex refractive indices n and k of Al which is a material constituting the bonding layer 414, SiO₂ which is a material constituting the dielectric layer 417, and GaN which is a material constituting the nitride semiconductor layer 404.

TABLE 1

Complex Refractive Index at Wavelength of 470 nm

| Material | n | k |
|---|---|---|
| Al | 0.675 | 5.6 |
| SiO₂ | 1.46 | 0 |
| GaN | 2.42 | 0 |

As shown in Table 1, Al has an extinction coefficient k of 5.6 (the extinction coefficient k is involved with absorption of light), and a portion of light is absorbed at an interface between the GaN film and the Al film. On the other hand, SiO₂ has an extinction coefficient k of 0, and therefore, light is not absorbed at an interface between the GaN film and the SiO₂ film. Therefore, by inserting the SiO₂ film between the GaN film and the Al film, the absorption of light at the interface between the GaN film and the Al film can be reduced, whereby the light output of the light emitting diode can be improved.

The result obtained from Table 1 will be described in greater detail with reference to FIGS. 22 and 23.

FIG. 22 is a diagram for describing the reflection of light on a GaN/Al reflective surface (FIG. 22(a) corresponds to GaN (101) and Al (114) of the first embodiment), and on a GaN/SiO₂/Al reflective surface (FIG. 22(b) corresponds to GaN (401), SiO₂ (417), and Al (414) in this embodiment). FIG. 23 is a diagram showing the dependency of a reflectance on the angle θ of incident light from the GaN film for the reflective surface structures of FIGS. 22(a) and 22(b), which was calculated by the rigorous coupled wave analysis (RCWA) method.

In this case, in order to study the dependency of a reflectance on the thickness of the SiO₂ film as well, the calculation was conducted for various thicknesses of the SiO₂ film which were 100 nm, 200 nm, 400 nm, 800 nm, and infinitely large (indicated as GaN/SiO₂).

As shown in FIGS. 22 and 23, the reflectance at the GaN/Al reflective surface is reduced to 85% or less when the incident angle is within the range of 0-60°, because a portion of light is absorbed by the surface of the Al film. On the other hand, the reflectance at the GaN/SiO₂/Al reflective surface is improved compared to the GaN/Al reflective surface, because a portion of light is reflected on the surface of the SiO₂ film, and a portion of light which is transmitted through the SiO₂ film is reflected on the surface of the Al film provided below the SiO₂ film. In particular, the reflectance is significantly improved when the incident angle is greater than or equal to 37° which is the critical angle of the GaN/SiO₂ interface. Note that there is a region in the vicinity of an incident angle of 40° in which the reflectance falls. This is because, when incident light is totally reflected on the GaN/SiO₂ interface, a portion of the light penetrates, as evanescent light, into the SiO₂ film, and is coupled to the Al film, resulting in a loss. The amount of the loss depends on a relationship between the penetration depth of the light and the thickness of the SiO₂ film. Therefore, for example, by causing the thickness of the SiO₂ film to be greater than about 140 nm which is the penetration depth when the incident angle is 40°, the loss can be significantly reduced. For example, as shown in FIG. 23, by causing the thickness of the SiO₂ film to be 800 nm, the loss can be substantially eliminated.

Next, in order to confirm the suggestion of FIG. 23, the result of an actually conducted experiment will be described.

The nitride semiconductor light emitting diode of this embodiment was actually fabricated, in which a SiO₂ film was used as the dielectric layer 417, and the thickness of the SiO₂ film was within the range of 80 nm or more and 800 nm or less. FIG. 24 shows the result of comparison of the total flux output of the nitride semiconductor light emitting diode of this embodiment with the total flux output of a light emitting diode having a structure in which a SiO₂ film was not inserted.

As can be seen from FIG. 24, when the SiO₂ film was inserted, the total flux output of the light emitting diode was improved by a factor of 1.4 compared to when a SiO₂ film was not inserted. It can also be seen that, when the thickness of the SiO₂ film was within the range of 0-400 nm, the total flux output increased as the thickness of the SiO₂ film increased. This is because, as described above, the coupling loss can be reduced by increasing the thickness of the SiO₂ film. Note that the improvement in the total flux output was confirmed when the thickness of the SiO₂ film was 80 nm or more, and therefore, it is preferable that the thickness of the SiO₂ film be 80 nm or more.

Note that excessively great thicknesses of the SiO₂ film are not preferable, because of insufficient heat dissipation of the light emitting diode. In fact, we experimentally confirmed that the light output of the light emitting diode was reduced when the thickness of the SiO₂ film was caused to be greater than 1000 nm. Therefore, it is preferable that the thickness of the SiO₂ film be 1000 nm or less.

As described above, by employing a nitride semiconductor light emitting diode having the structure of this embodiment, the light output of the light emitting diode can be easily improved.

### Fifth Embodiment

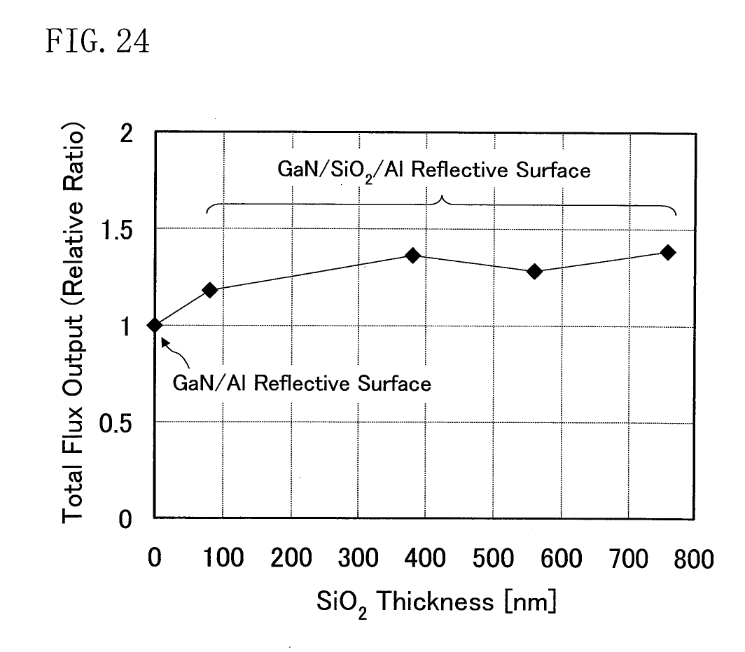

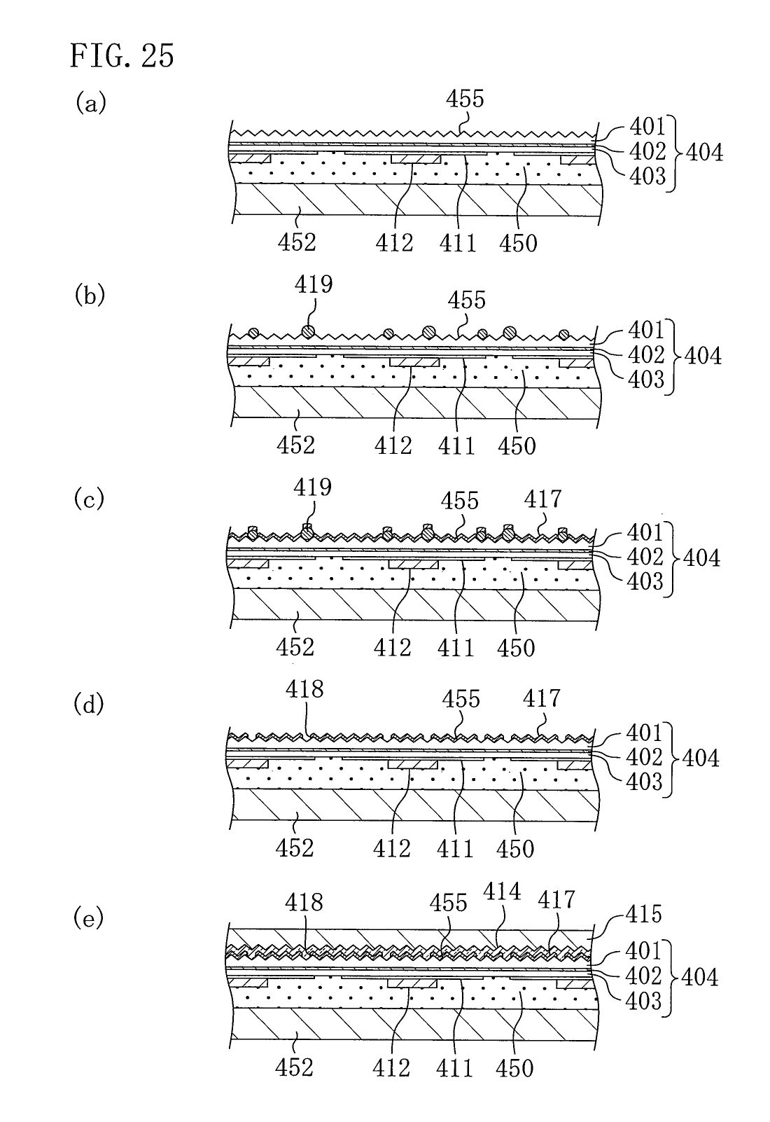

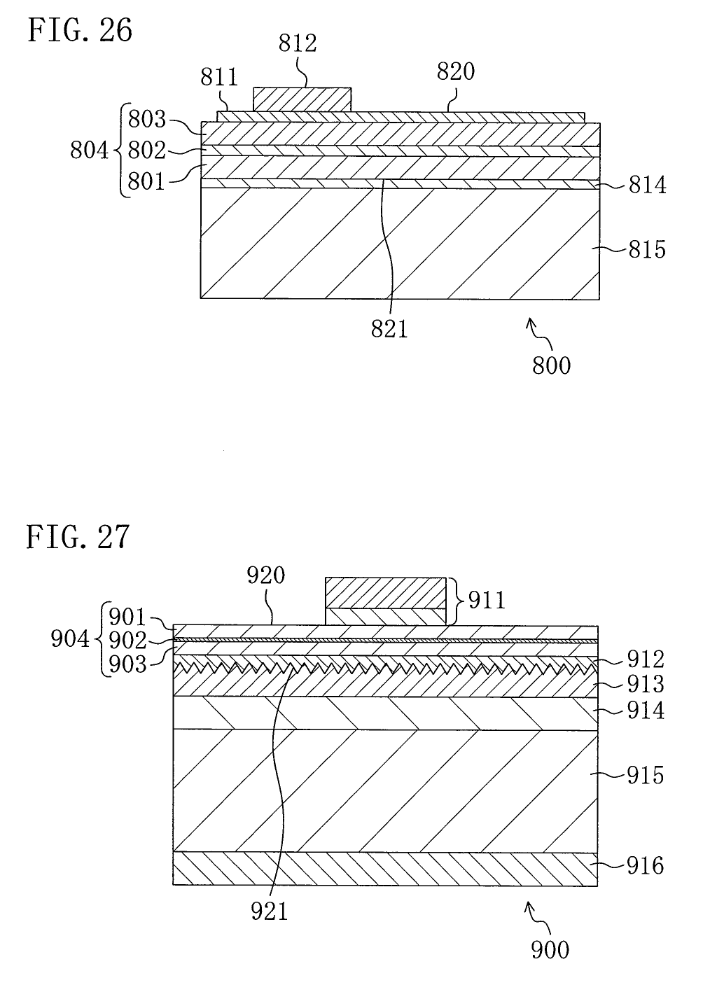

Next, a nitride semiconductor light emitting diode according to a fifth embodiment of the present invention will be described with reference to FIGS. 25(a)-25(e). The nitride semiconductor light emitting diode of this embodiment has the same structure as that of the fourth embodiment. The nitride semiconductor light emitting diode of this embodiment is fabricated by a second fabrication method which is different from the first fabrication method of the fourth embodiment. Therefore, the structure will not be described, and the second fabrication method will be described with reference to FIGS. 25(a)-25(e).

Initially, as shown in FIG. 25(a), the uneven surface 455 is formed on the n-type GaN layer 401 by steps similar to those of FIGS. 2(a)-2(e) of the fabrication method of the first embodiment of the present invention, while the second substrate 452 adheres to the nitride semiconductor layer 404 via the adhesive layer 450.

Next, as shown in FIG. 25(b), fine metal particles 419 are dispersed on the uneven surface 455. Specifically, the fine metal particles 419 are dispersed by, for example, preparing a liquid which is pure water containing a large amount of metal powder made of fine metal particles having a diameter of 2-3 μm, uniformly applying the liquid onto the uneven surface 455, and thereafter, allowing the liquid to dry by natural evaporation.

Note that the metal powder made of fine metal particles having a diameter of 2-3 μm can be produced by, for example, an atomizing method (particles are produced by blowing water, air, gas, or the like on a melted metal), and a variety of such metal powder is commercially available. In this embodiment, metal powder including fine metal particles made of Ni having a diameter of 2-3 μm is employed.

Next, as shown in FIG. 25(c), the dielectric layer 417 made of, for example, SiO₂ or AlₓO_{y} (more specifically, Al₂O₂) is deposited by an electron beam deposition method. In this case, the dielectric layer 417 is deposited on the fine metal particles 419 as well as on the uneven surface 455.

Next, the fine metal particles 419 made of Ni are etched and removed by wet etching using hydrochloric acid. As a result, as shown in FIG. 25(d), the openings 418 are provided in the dielectric layer 417. Note that a size or a shape of the opening 418 formed here varies depending on a size of the fine metal particle 419, and therefore, has variations in contrast to the relatively uniform size or shape of the opening 418 of the fourth embodiment described above.

Next, as shown in FIG. 25(e), after a metal made of III atoms such as Al or the like or an alloy thereof is deposited on the dielectric layer 417 to form the bonding layer 414, the support substrate 415 made of a conductive material is formed, contacting an upper surface of the bonding layer 414.

The subsequent steps are similar to those of FIGS. 3(c) and 3(d) of the method for fabricating the nitride semiconductor light emitting diode 100 of the first embodiment.

As described above, by using the fabrication method of this embodiment, the nitride semiconductor light emitting diode of the fourth embodiment can be more easily fabricated. Although Al is used as the reflective films of the nitride semiconductor light emitting diodes of the fourth and fifth embodiments, needless to say, a multilayer metal film made of a thin Al film/a high-reflectance metal, such as an Al (2 nm)/Ag (0.2 nm) film described in the third embodiment, can be employed.

### INDUSTRIAL APPLICABILITY

According to the present invention, a single-sided electrode type or p-side up type nitride semiconductor light emitting diode can be achieved in which the reflection efficiency at the reflective surface is high and the operating voltage can be reduced, and the adhesiveness between the metal layer constituting the reflective surface and the nitride semiconductor layer is high. The structure of the present invention can provide a high-luminance light emitting diode which emits light having a wavelength ranging from ultraviolet to blue and green. Therefore, the light emitting diode of the present invention is useful as, for example, a liquid crystal backlight module for thin liquid crystal display devices, such as liquid crystal monitors, liquid crystal televisions, and the like, or an illumination light source which needs to illuminate a large area.

### DESCRIPTION OF REFERENCE CHARACTERS

100, 200, 300, 400 Light Emitting Diode
101, 201, 301, 401 N-type GaN Layer
102, 202, 303, 402 Light Emission Layer
104, 204, 304, 404 Nitride Semiconductor Layer
105 Exposure Surface
111, 211, 311, 411 Transparent Electrode
112, 212, 312, 412 p-Electrode
114, 214, 314, 414 Bonding Layer
115, 215, 315, 415 Support Substrate
116, 216, 316, 416 Backside Electrode
120, 320, 420 Light Emitting Surface
121, 321, 421 Reflective surface
130a-130e Generated Light
150, 250, 450 Adhesive Layer
151, 251 First Substrate
152, 252, 452 Second Substrate
153 Vessel
154 Aqueous KOH Solution
155, 455 Uneven Surface
156 Blade
160, 260 n-Electrode Wiring Portion
161, 261 p-Electrode Wiring Portion
162, 262 Resin Adhesive
163, 263 Au Wire
164 Resin
190 Substrate
203 p-type GaN Layer
205 Opening
206 Opening
213 n-Electrode
220 Light Emitting Surface
221 Reflective surface
265 Resin
317 Reflective layer
417 Dielectric Layer (Low Refractive Index Film)
418 Opening
419 Fine Metal Particle
460 Resist
461 Resist Opening

1. A nitride semiconductor light emitting diode comprising:
a p-type layer made of a p-type nitride semiconductor;
a light emission layer provided on a lower surface of the p-type layer;
an n-type layer made of an n-type nitride semiconductor, provided on a lower surface of the light emission layer; and
a bonding layer provided, contacting the n-type layer,
wherein
an uneven topography having a plurality of sloped surfaces is provided on a surface contacting the bonding layer of the n-type layer, and
the bonding layer is made of a metal made of Group III atoms or an alloy containing the Group III atoms.

2. The nitride semiconductor light emitting diode of claim 1, wherein
a portion of or all of the plurality of sloped surfaces are formed of a crystal face of a nitride semiconductor.

3. The nitride semiconductor light emitting diode of claim 2, wherein
the crystal face is a {1-10-1} plane.

4. The nitride semiconductor light emitting diode of claim 1, wherein the Group III atoms are Al.

5. The nitride semiconductor light emitting diode of claim 1, further comprising:
a reflective layer provided in a lower portion of the bonding layer,
wherein
the bonding layer has a thickness which is smaller than or equal to a penetration depth of light emitted from the light emission layer with respect to a material constituting the bonding layer.

6. The nitride semiconductor light emitting diode of claim 5, wherein
the reflective layer is made of a metal made of Ag or an alloy containing Ag.

7. The nitride semiconductor light emitting diode of claim 1, further comprising:
a dielectric layer formed between the n-type layer and the bonding layer, and having a plurality of openings,
wherein
the n-type layer and the bonding layer contact each other via the openings.

8. The nitride semiconductor light emitting diode of claim 7, wherein
the dielectric layer is made of a monolayer or multilayer film made of one or at least one material selected from the group consisting of SiO₂, TiO₂, MgF₂, CaF₂, SiₓN_{y}, AlₓO_{y}, and LiF.

9. The nitride semiconductor light emitting diode of claim 7, wherein
the dielectric layer is made of a dielectric material having a lower refractive index with respect to a wavelength of the emitted light than that of the nitride semiconductor.

10. The nitride semiconductor light emitting diode of claim 9, wherein
the dielectric layer has a thickness of 80 nm or more.

11. The nitride semiconductor light emitting diode of claim 10, wherein
the dielectric layer has a thickness of 1000 nm or less.
